(19) United States
(12) Patent Application Publication
(10) Pub. No.: US 2026/0180321 A1
(43) Pub. Date: Jun. 25, 2026

(54) ELECTROSTATIC DISCHARGE (ESD) PROTECTION CIRCUIT AND METHOD OF OPERATING THE SAME

(71) Applicants: TAIWAN SEMICONDUCTOR MANUFACTURING COMPANY, LTD., Hsinchu (TW); TSMC CHINA COMPANY, LIMITED, Shanghai (CN)

(72) Inventors: Huan-Neng CHEN, Hsinchu (TW); Shao-Yu LI, Hsinchu (TW); CunCun CHEN, Hsinchu (TW)

(21) Appl. No.: 19/009,439

(22) Filed: Jan. 3, 2025

(30) Foreign Application Priority Data
Dec. 19, 2024 (CN) 202411886414.9

(51) Int. Cl. H02H 9/04; H10D 89/60

(52) U.S. Cl. CPC H02H 9/046; H10D 89/611

(57) ABSTRACT

An integrated circuit includes a buffer circuit coupled between a first node and a second node, an input/output (IO) pad coupled to the buffer circuit, a first clamp circuit coupled between the IO pad and the second node, and a second clamp circuit coupled between the IO pad and the first node. The buffer circuit is configured to output a first signal to the IO pad. The first clamp circuit is configured to clamp a first electrostatic discharge (ESD) event at the IO pad or the second node. The second clamp circuit is configured to clamp a second ESD event at the IO pad or the first node.

### PRIORITY CLAIM AND CROSS-REFERENCE

This application claims to China Application No. 202411886414.9, filed Dec. 19, 2024, which is incorporated herein by reference in its entirety.

### BACKGROUND

The recent trend in miniaturizing integrated circuits (ICs) has resulted in smaller devices which consume less power, yet provide more functionally at higher speeds than before. The miniaturization process has also increased the devices' susceptibility to electrostatic discharge (ESD) events due to various factors, such as thinner dielectric thicknesses and associated lowered dielectric breakdown voltages. ESD is one of the causes of electronic circuit damage and is also one of the considerations in semiconductor advanced technology.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a schematic block diagram of an integrated circuit, in accordance with some embodiments.

FIG. 1B is a schematic block diagram of an integrated circuit, in accordance with some embodiments.

FIG. 2A is a circuit diagram of an integrated circuit, in accordance with some embodiments.

FIG. 2B is a circuit diagram of an integrated circuit, in accordance with some embodiments.

FIG. 3A is a circuit diagram of an integrated circuit, in accordance with some embodiments.

FIG. 3B is a circuit diagram of an integrated circuit, in accordance with some embodiments.

FIG. 4A is a circuit diagram of an integrated circuit, in accordance with some embodiments.

FIG. 4B is a circuit diagram of an integrated circuit, in accordance with some embodiments.

FIG. 5A is a circuit diagram of an integrated circuit, in accordance with some embodiments.

FIG. 5B is a circuit diagram of an integrated circuit, in accordance with some embodiments.

FIG. 6 is a diagram of a circuit, in accordance with some embodiments.

FIGS. 7A-7G are corresponding block diagrams of corresponding resistive networks, in accordance with some embodiments.

FIG. 8A is a diagram of an integrated circuit, in accordance with some embodiments.

FIG. 8B is a diagram of an integrated circuit, in accordance with some embodiments.

FIGS. 8C-8D are corresponding cross-sectional views of an integrated circuit, in accordance with some embodiments.

FIG. 9 is a diagram of a circuit, in accordance with some embodiments.

FIG. 10 is a flowchart of a method of operating an ESD circuit, in accordance with some embodiments.

FIG. 11 is a functional flow chart of method of manufacturing an IC device, in accordance with some embodiments.

FIG. 12 is a flowchart of a method of forming or manufacturing an integrated circuit in accordance with some embodiments.

FIG. 13 is a flowchart of a method of generating a layout design of an integrated circuit, in accordance with some embodiments.

FIG. 14 is a schematic view of a system for designing an IC layout design and manufacturing an IC circuit, in accordance with some embodiments.

FIG. 15 is a block diagram of an integrated circuit (IC) manufacturing system, and an IC manufacturing flow associated therewith, in accordance with at least one embodiment of the present disclosure.

### DETAILED DESCRIPTION

The following disclosure provides different embodiments, or examples, for implementing features of the provided subject matter. Specific examples of components, materials, values, steps, arrangements, or the like, are described below to simplify the present disclosure. These are, of course, merely examples and are not limiting. Other components, materials, values, steps, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some embodiments, an integrated circuit includes a buffer circuit. In some embodiments, the buffer circuit is coupled between a first node and a second node.

In some embodiments, the integrated circuit further includes an input/output (IO) pad. In some embodiments, the IO pad is coupled to the buffer circuit. In some embodiments, the buffer circuit is configured to output a first signal to the IO pad.

In some embodiments, the integrated circuit further includes a first clamp circuit. In some embodiments, the first clamp circuit is coupled between the IO pad and the second node. In some embodiments, the first clamp circuit is configured to clamp a first electrostatic discharge (ESD) event at the IO pad or the second node.

In some embodiments, the integrated circuit further includes a second clamp circuit. In some embodiments, the second clamp circuit is coupled between the IO pad and the first node. In some embodiments, the second clamp circuit is configured to clamp a second ESD event at the IO pad or the first node.

In some embodiments, the first clamp circuit includes a first ESD detection circuit. In some embodiments, the first ESD detection circuit is coupled between the IO pad and the second node.

In some embodiments, the second clamp circuit includes a second ESD detection circuit. In some embodiments, the second ESD detection circuit is coupled between the IO pad and the first node.

In comparison with other approaches, the integrated circuit of the present disclosure has better ESD discharging capability and performance than other approaches while occupying less area.

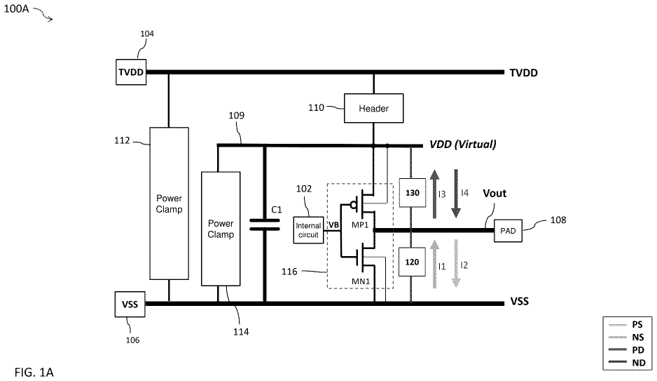

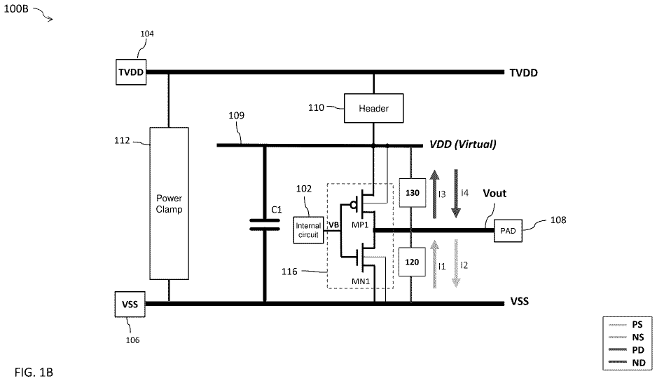

FIG. 1A is a schematic block diagram of an integrated circuit 100A, in accordance with some embodiments.

Integrated circuit 100A comprises an internal circuit 102, a voltage supply node 104, a reference voltage supply node 106, an input/output (IO) pad 108, a voltage supply rail 109, a header circuit 110, a power clamp 112, a power clamp 114, a capacitor C1, a buffer circuit 116, an ESD clamp 120 and an ESD clamp 130.

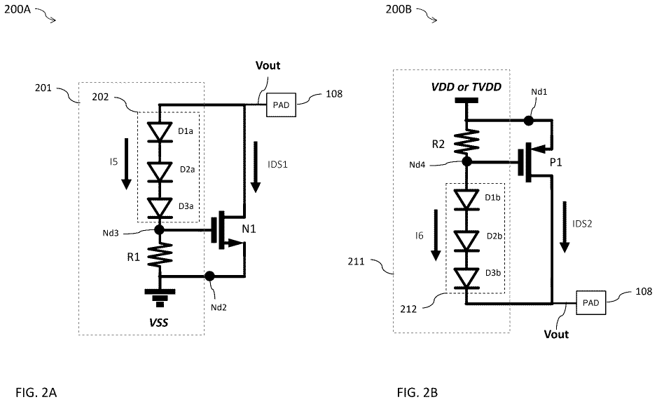

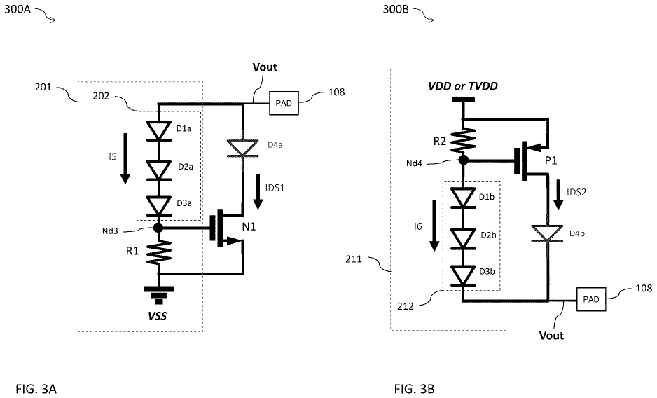

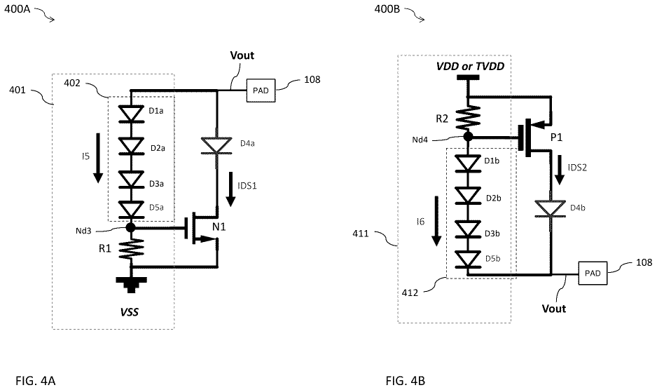

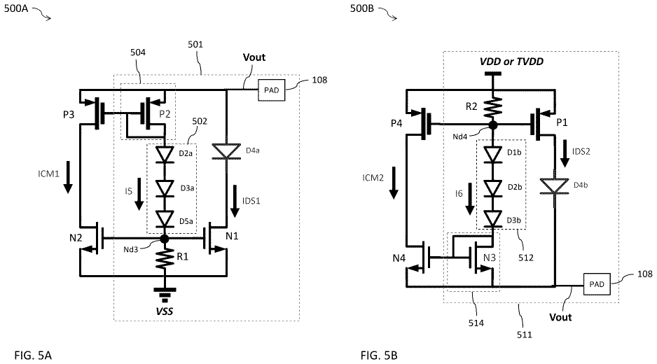

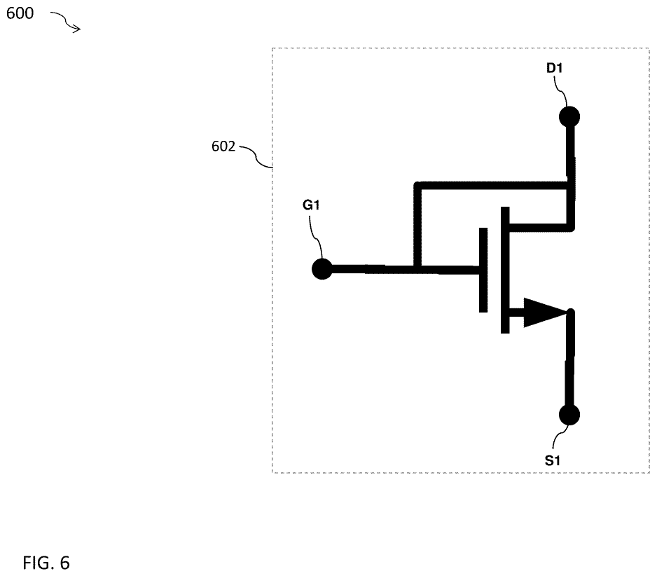

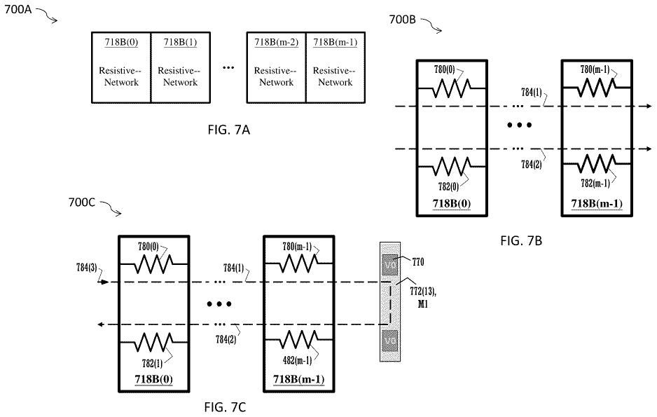

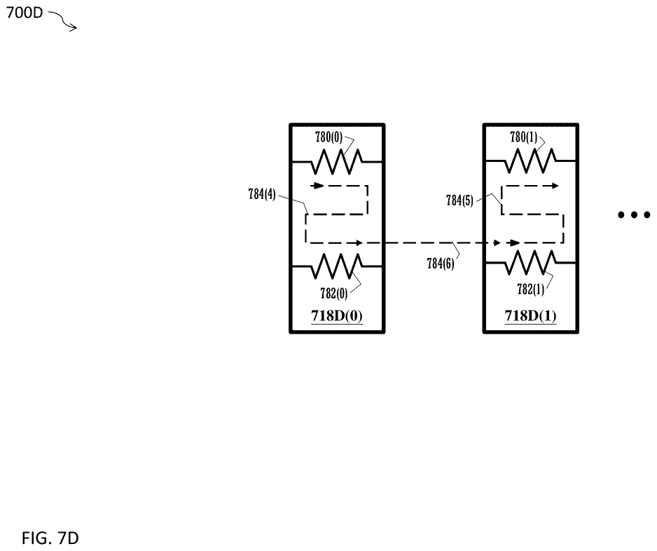

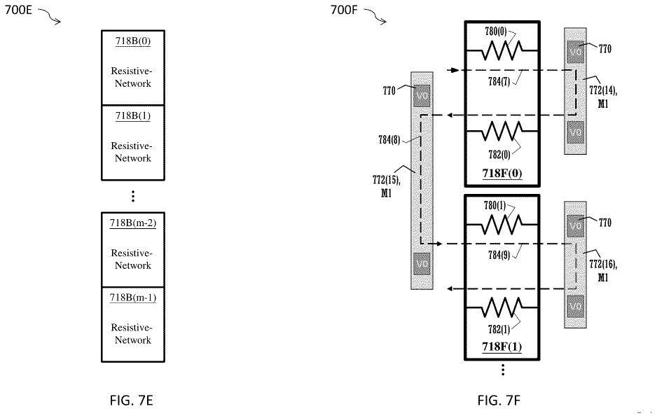

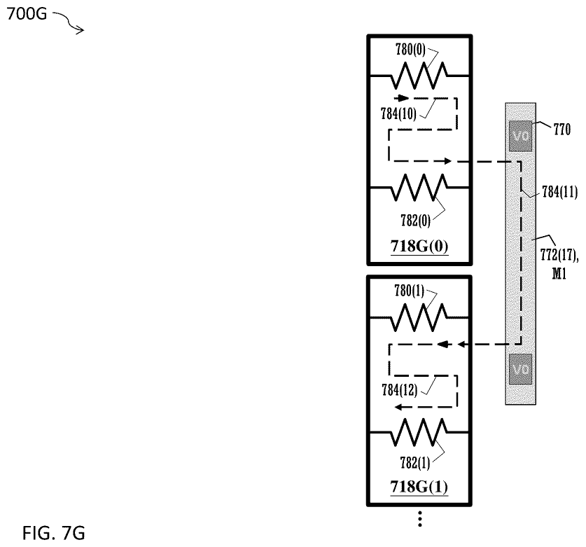

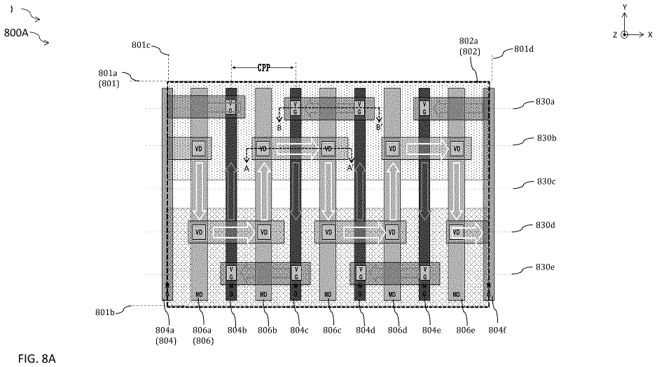

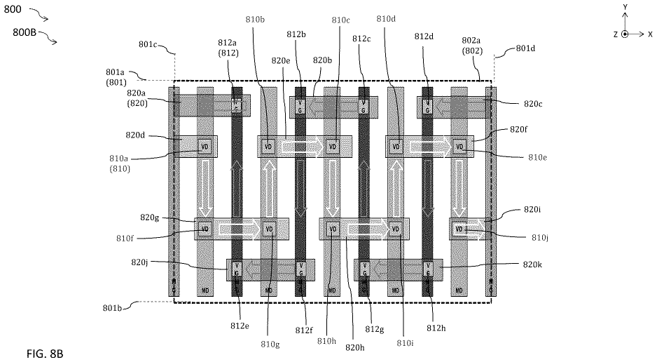

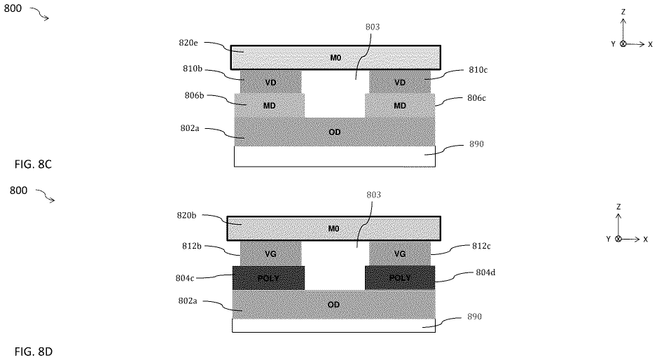

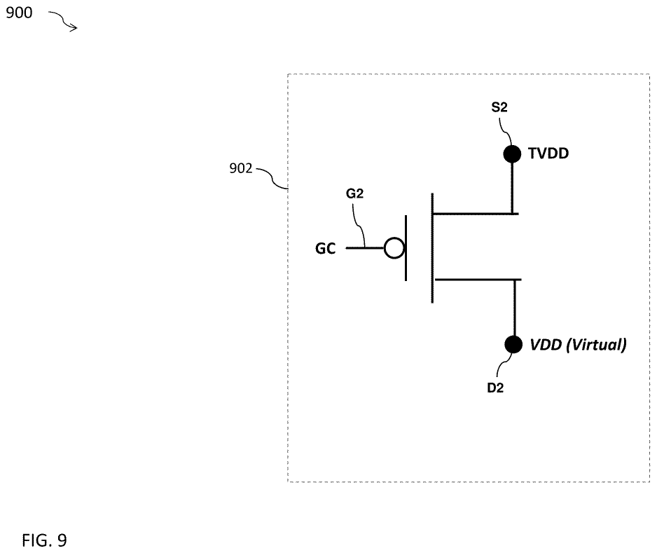

In some embodiments, at least one or more of integrated circuit 100A, 100B (FIG. 1B), 200A-200B (FIGS. 2A-2B), 300A-300B (FIGS. 3A-3B), 400A-400B (FIGS. 4A-4B), 500A-500B (FIGS. 5A-5B), 600 (FIG. 6), 700A-700G (FIGS. 7A-7G), 800 (FIGS. 8A-8D) or 900 (FIG. 9) is incorporated on a single integrated circuit (IC), or on a single semiconductor substrate. In some embodiments, at least integrated circuit 100A, 100B (FIG. 1B), 200A-200B (FIGS. 2A-2B), 300A-300B (FIGS. 3A-3B), 400A-400B (FIGS. 4A-4B), 500A-500B (FIGS. 5A-5B), 600 (FIG. 6), 700A-700G (FIGS. 7A-7G), 800 (FIGS. 8A-8D) or 900 (FIG. 9) includes one or more ICs incorporated on one or more single semiconductor substrates.

Internal circuit 102 is coupled to the IO pad 108 by the buffer circuit 116. Internal circuit 102 is configured to output a signal VB to the buffer circuit 116. The buffer circuit 116 is configured to output a signal Vout to the IO pad 108. In some embodiments, signal Vout is inverted from signal VB. In some embodiments, at least one of signal VB or signal Vout is an IO signal. In some embodiments, the positions of internal circuit 102 and I/O pad 108 are switched with each other. In some embodiments, the internal circuit 102 is configured to receive an IO signal (e.g., Vout) from the IO pad 108.

In some embodiments, internal circuit 102 is coupled to voltage supply node 104 (e.g. TVDD) and reference voltage supply node 106 (e.g., VSS). In some embodiments, internal circuit 102 is configured to receive a supply voltage TVDD from voltage supply node 104 (e.g. TVDD), and a reference voltage VSS from reference voltage supply node 106 (e.g., VSS).

In some embodiments, internal circuit 102 is coupled to voltage supply rail 109 (e.g. VDD) and reference voltage supply node 106 (e.g., VSS). In some embodiments, internal circuit 102 is configured to receive a virtual supply voltage VDD from voltage supply rail 109 (e.g. VDD), and the reference voltage VSS from reference voltage supply node 106 (e.g., VSS).

Internal circuit 102 includes circuitry configured to generate the signal VB output to the buffer circuit 116. In some embodiments, internal circuit 102 includes circuitry configured to process one or more IO signals (e.g., Vout) received from the IO pad 108.

In some embodiments, internal circuit 102 comprises core circuitry configured to operate at the supply voltage TVDD of voltage supply node 104 or the supply voltage VDD of the voltage supply rail 109. In some embodiments, internal circuit 102 comprises core circuitry configured to operate at a voltage lower than the supply voltage TVDD of voltage supply node 104 or the supply voltage VDD of the voltage supply rail 109. In some embodiments, internal circuit 102 includes at least one n-type or p-type transistor device. In some embodiments, internal circuit 102 includes at least a logic gate cell. In some embodiments, a logic gate cell includes an AND, OR, NAND, NOR, XOR, INV, AND-OR-Invert (AOI), OR-AND-Invert (OAI), MUX, Flip-flop, BUFF, Latch, delay, or clock cells. In some embodiments, internal circuit 102 includes at least a memory cell. In some embodiments, the memory cell includes a static random access memory (SRAM), a dynamic RAM (DRAM), a resistive RAM (RRAM), a magnetoresistive RAM (MRAM) or read only memory (ROM). In some embodiments, internal circuit 102 includes one or more active or passive elements. Examples of active elements include, but are not limited to, transistors and diodes. Examples of transistors include, but are not limited to, metal oxide semiconductor field effect transistors (MOSFET), complementary metal oxide semiconductor (CMOS) transistors, bipolar junction transistors (BJT), high voltage transistors, high frequency transistors, p-channel and/or n-channel field effect transistors (PFETs/NFETs), etc.), FinFETs, and planar MOS transistors with raised source/drain. Examples of passive elements include, but are not limited to, capacitors, inductors, fuses, and resistors.

Other configurations, number of devices or types of devices in internal circuit 102 are within the scope of the disclosure.

Voltage supply node 104 is coupled to power clamp 112 and header circuit 110. Reference voltage supply node 106 is coupled to power clamp 112, power clamp 114, capacitor C1 and ESD clamp 120.

Voltage supply node 104 is configured to receive supply voltage TVDD for normal operation of internal circuit 102. Similarly, reference voltage supply node 106 is configured to receive reference supply voltage VSS for normal operation of internal circuit 102. Voltage supply rail 109 is configured to receive virtual supply voltage (e.g., supply voltage VDD) for normal operation of internal circuit 102. In some embodiments, at least voltage supply node 104 is a voltage supply pad. In some embodiments, at least voltage supply rail 109 is a voltage supply pad. In some embodiments, at least reference voltage supply node 106 is a reference voltage supply pad. In some embodiments, a pad is at least a conductive surface, a pin, a node or a bus. Voltage supply node 104 or reference voltage supply node 106 is also referred to as a power supply voltage bus or rail. In some embodiments, voltage supply rail 109 is also referred to as a virtual voltage supply pad. In the example configuration in FIGS. 1A-1B, 2A-2B, 3A-3B, 4A-4B, 5A-5B, 6, 7A-7G, 8A-8D or 9, supply voltage TVDD is a positive supply voltage, voltage supply node 104 is a positive power supply voltage, supply voltage VDD is a positive supply voltage, voltage supply rail 109 is a positive power supply voltage, reference supply voltage VSS is a ground supply voltage, and reference voltage supply node 106 is a ground voltage terminal. Other power supply arrangements are within the scope of the present disclosure.

Buffer circuit 116 is coupled to input circuit 102, voltage supply rail 109, reference voltage supply node 106, IO pad 108, ESD clamp circuit 120 and ESD clamp circuit 130.

Buffer circuit 116 is configured to receive signal VB from internal circuit 102. Buffer circuit 116 is configured to output signal Vout to IO pad 108. In some embodiments, buffer circuit 108 is an IO buffer circuit. In some embodiments, buffer circuit 108 is an inverter.

Buffer circuit 116 includes an N-type Metal Oxide Semiconductor (NMOS) transistor MN1 and a P-type Metal Oxide Semiconductor (PMOS) transistor MP1.

Each of a first end of power clamp 114, a first end of capacitor C1, voltage supply rail 109, a source of PMOS transistor MP1, and a bulk of PMOS transistor MP1 and a first end of ESD clamp 130 are coupled together.

Each of an output of input circuit 102, a gate of PMOS transistor MP1 and a gate of NMOS transistor MN1 are coupled together.

Each of a second end of power clamp 114, a second end of capacitor C1, reference node 106, a source of NMOS transistor MN1 and a first end of ESD clamp 120 are coupled together.

Each of a drain of NMOS transistor MN1, a drain of PMOS transistor MP1, a second end of ESD clamp 130, a second end of ESD clamp 120 and IO pad 108 are coupled together.

Other configurations, number of devices or types of devices in buffer circuit 116 are within the scope of the disclosure.

Capacitor C1 is coupled between voltage supply rail 109 and reference node 106. In some embodiments, capacitor C1 is a transistor-coupled capacitor. For example in some embodiments, capacitor C1 is a transistor having a drain and source coupled together thereby forming a transistor-coupled capacitor.

Other configurations, number of devices or types of devices in capacitor C1 are within the scope of the disclosure.

IO pad 108 is coupled to buffer circuit 102, ESD clamp circuit 120 and ESD clamp circuit 130. IO pad 108 is configured to receive signal Vout from buffer circuit 116. IO pad 108 is at least a pin that is coupled to internal circuit 102. In some embodiments, IO pad 108 is a node, a bus or a conductive surface that is coupled to internal circuit 102.

Other configurations, number of devices or types of devices in IO pad 108 are within the scope of the disclosure.

Header circuit 110 is coupled between voltage supply node 104 and voltage supply rail 109.

Header circuit 110 is coupled to the voltage supply node 104 of the voltage supply TVDD and a voltage supply rail 109. Header circuit 110 is configured to receive a first voltage from the first voltage supply TVDD. In some embodiments, the first voltage supply TVDD is referred to as true VDD (TVDD). In some embodiments, the first voltage supply TVDD is a voltage supply positioned external of integrated circuit 100A or 100B. In some embodiments, the first voltage supply TVDD is a voltage supply positioned internal of integrated circuit 100A or 100B.

Header circuit 110 is configured to receive a control signal GC (shown in FIG. 9). In some embodiments, header circuit 110 is configured to be turned on or off based on control signal GC. In some embodiments, header circuit 110 is configured to be turned on, and is configured to provide a voltage to the voltage supply rail 109 (referred to as a virtual voltage supply (VDD) or a second voltage supply VDD). The first voltage of the first voltage supply TVDD is the same as the second voltage of the second supply voltage VDD. In some embodiments, the first voltage of the first voltage supply TVDD is different from the second voltage of the second supply voltage VDD.

Header circuit 110 is configured to provide the second voltage to voltage supply rail 109 responsive to the control signal GC. Header circuit 110 is configured to gate the power provided to integrated circuit 100A or 100B.

In some embodiments, based on different power states of the integrated circuit 100A or 100B, header circuit 110 is configured to switch on, and thereby provide power to the voltage supply rail 109 of the integrated circuit 100A or 100B responsive to the control signal GC, or header circuit 110 is configured to switch off and thereby cut off power provided to the voltage supply rail 109 responsive to the control signal GC. For example, when the integrated circuit 100A or 100B is in a sleep mode or a standby mode, header circuit 110 is configured to be turned off, and the power provided to integrated circuit 100A or 100B is thereby cut off. For example, when the integrated circuit 100A or 100B is in an active mode, header circuit 110 is configured to be turned on, and thereby provides power to the integrated circuit 100A or 100B. In some embodiments, the control signal GC is received from a power management controller circuit (not shown). Header circuit 110 is configured to reduce leakage current within the integrated circuit 100A or 100B, and therefore reduce the power consumed by the integrated circuit 100A or 100B.

In some embodiments, the second voltage of the second voltage supply VDD is referred to as gated power (e.g., VDD) from the header circuit 110. In some embodiments, the first voltage of the first voltage supply TVDD is referred to as ungated power (e.g., TVDD).

In some embodiments, the header circuit 110 is not included in integrated circuit 100A or 100B. In these embodiments, the voltage supply node 104 is directly coupled to the voltage supply rail 109. In these embodiments, the voltage supply node 104 and the voltage supply rail 109 are part of a same structure. In these embodiments, at least one of power clamp 112 or power clamp 114 are not included.

Other configurations, number of devices or types of devices in header circuit 110 are within the scope of the disclosure.

Power clamp 112 is coupled between voltage supply node 104 and reference voltage supply node 106. In some embodiments, power clamp 112 is configured to absorb direct ESD stress between voltage supply node 104 and reference voltage supply node 106, thereby protecting integrated circuit 100A or 100B from one or more ESD events. In some embodiments, the power clamp 112 is configured to provide a current path between the power supply pad (e.g., voltage supply node 104) and the ground pad (e.g., reference voltage supply node 106) during one or more ESD events.

In some embodiments, power clamp 112 includes one or more NMOS or PMOS transistors configured as a clamp circuit. In some embodiments, power clamp 112 includes one or more diodes configured as a clamp circuit. In some embodiments, power clamp 112 includes one or more of an NMOS transistor, an PMOS transistor, a diode, a resistor or a capacitor. In some embodiments, power clamp 112 further includes one or more trigger circuits. In some embodiments, power clamp 112 includes a silicon-controlled rectifier (SCR) device.

Other configurations, number of devices or types of devices in power clamp 112 are within the scope of the disclosure.

Power clamp 114 is coupled between voltage supply rail 109 and reference voltage supply node 106. In some embodiments, power clamp 114 is configured to absorb direct ESD stress between voltage supply rail 109 and reference voltage supply node 106, thereby protecting integrated circuit 100A from one or more ESD events. In some embodiments, the power clamp 114 is configured to provide a current path between the voltage supply rail 109 and the ground pad (e.g., reference voltage supply node 106) during one or more ESD events.

In some embodiments, power clamp 114 includes one or more NMOS or PMOS transistors configured as a clamp circuit. In some embodiments, power clamp 114 includes one or more diodes configured as a clamp circuit. In some embodiments, power clamp 114 includes one or more of an NMOS transistor, an PMOS transistor, a diode, a resistor or a capacitor. In some embodiments, power clamp 114 further includes one or more trigger circuits. In some embodiments, power clamp 114 includes a silicon-controlled rectifier (SCR) device.

Other configurations, number of devices or types of devices in power clamp 114 are within the scope of the disclosure.

Diode 110 is coupled between voltage supply node 104 and IO pad 108. An anode of diode 110 is coupled to internal circuit 102, IO pad 108 and a cathode of diode 112. A cathode of diode 110 is coupled to voltage supply node 104 and ESD clamp 120. In some embodiments, diode 110 is a pull-up diode or referred to as a p+ diode. For example, in these embodiments, the p+-diode is formed between a p-well region (not shown) and an n-well region (not shown), and the n-well region is connected to VDD.

Diode 112 is coupled between reference voltage supply node 106 and IO pad 108. An anode of diode 112 is coupled to reference voltage supply node 106 and ESD clamp 120. A cathode of diode 112 is coupled to internal circuit 102, IO pad 108 and the anode of diode 110. In some embodiments, diode 112 is a pull-down diode or referred to as an n+ diode. For example, in these embodiments, the n+-diode is formed between an n+ junction (not shown) and a p-substrate (not shown), and the P-substrate is connected to ground or VSS.

Diodes 110 and 112 are configured to have a minimal impact on the normal behavior (e.g., no ESD conditions or events) of internal circuit 102 or integrated circuit 100A. In some embodiments, an ESD event occurs when an ESD voltage or current higher than a level of voltage or current expected during the normal operation of internal circuit 102 is applied to at least voltage supply node 104, reference voltage supply node 106 or IO pad 108.

ESD clamp 120 is coupled between IO pad 108 and reference voltage supply node 106 (e.g., VSS). When no ESD event occurs, ESD clamp 120 is turned off. For example, when no ESD event occurs, ESD clamp 120 is turned off, and is therefore a nonconductive device or circuit during the normal operation of internal circuit 102. In other words, ESD clamp 120 is turned off or is non-conductive in the absence of an ESD event.

If an ESD event occurs, ESD clamp 120 is configured to sense the ESD event, and is configured to turn on and provide a current shunt path between IO pad 108 and reference voltage supply node 106 (e.g., VSS) to thereby discharge the ESD current. For example, when an ESD event occurs, the voltage difference across the ESD clamp 120 is equal to or greater than a threshold voltage of ESD clamp 120, and ESD clamp 120 is turned ON thereby conducting current between IO pad 108 and reference voltage supply node 106 (e.g., VSS).

During an ESD event, ESD clamp 120 is configured to turn on and discharge an ESD current (I1 or I2) in a forward ESD direction (e.g., current I1) or a reverse ESD direction (e.g., current I2). The forward ESD direction (e.g., current I1) is from the reference voltage supply node 106 (e.g., VSS) to the IO pad 108. The reverse ESD direction (e.g., current I2) is from IO pad 108 to reference voltage supply node 106 (e.g., VSS).

During a negative-to-VSS ESD surge, ESD clamp 120 is configured to turn on and discharge the ESD current I1 in a forward ESD direction from the reference voltage supply node 106 (e.g., VSS) to the IO pad 108, and is referred to as a negative-to-VSS (NS) mode. In some embodiments, ESD clamp 120 is configured to turn on, after an NS mode of ESD, and discharge the ESD current I1 in the forward ESD direction from the reference voltage supply node 106 (e.g., VSS) to the IO pad 108.

During a positive-to-VSS ESD surge on IO pad 108, ESD clamp 120 is configured to turn on and discharge the ESD current I2 in a reverse ESD direction from IO pad 108 to reference voltage supply node 106 (e.g., VSS), and is referred to as a positive-to-VSS (PS) mode. In some embodiments, ESD clamp 120 is configured to turn on, after a PS mode of ESD, and ESD clamp 120 is configured to discharge the ESD current I2 in the reverse ESD direction from IO pad 108 to reference voltage supply node 106 (e.g., VSS).

In some embodiments, ESD clamp 120 is a transient clamp. For example, in some embodiments, ESD clamp 120 is configured to handle transient or rapid ESD events, e.g., rapid changes in voltage and/or current from the ESD event. During the transient or rapid ESD, the ESD clamp 120 is configured to turn on very quickly to provide a shunt path between IO pad 108 and reference voltage supply node 106 (e.g., VSS) before the ESD event can cause damage to one or more elements within integrated circuit 100A or 100B. In some embodiments, ESD clamp 120 is configured to turn off slower than it turns on.

In some embodiments, ESD clamp 120 is a static clamp. In some embodiments, static clamps are configured to provide a static or steady-state voltage and current response. For example, static clamps are turned-on by a fixed voltage level.

Other types of clamp circuits, configurations and arrangements of ESD clamp 120 are within the scope of the present disclosure.

ESD clamp 130 is coupled between IO pad 108 and voltage supply rail 109 (e.g., VDD). When no ESD event occurs, ESD clamp 130 is turned off. For example, when no ESD event occurs, ESD clamp 130 is turned off, and is therefore a nonconductive device or circuit during the normal operation of internal circuit 102. In other words, ESD clamp 130 is turned off or is non-conductive in the absence of an ESD event.

If an ESD event occurs, ESD clamp 130 is configured to sense the ESD event, and is configured to turn on and provide a current shunt path between IO pad 108 and voltage supply rail 109 (e.g., VDD) to thereby discharge the ESD current. For example, when an ESD event occurs, the voltage difference across the ESD clamp 130 is equal to or greater than a threshold voltage of ESD clamp 130, and ESD clamp 130 is turned ON thereby conducting current between IO pad 108 and voltage supply rail 109 (e.g., VDD).

During an ESD event, ESD clamp 130 is configured to turn on and discharge an ESD current (I3 or I4) in a forward ESD direction (e.g., current I3) or a reverse ESD direction (e.g., current I4). The forward ESD direction (e.g., current I3) is from the IO pad 108 to the voltage supply rail 109 (e.g., VDD). The reverse ESD direction (e.g., current I4) is from the voltage supply rail 109 (e.g., VDD) to the IO pad 108.

During a positive-to-VDD (PD) ESD surge on the IO pad 108, ESD clamp 130 is configured to turn on and discharge the ESD current I3 in a forward ESD direction from the IO pad 108 to the voltage supply rail 109 (e.g., VDD), and is referred to as a positive-to-VDD (PD) mode. In some embodiments, ESD clamp 130 is configured to turn on, after a PD mode of ESD, and discharge the ESD current I3 in the forward ESD direction from the IO pad 108 to the voltage supply rail 109 (e.g., VDD).

During a negative-to-VDD (ND) ESD surge, ESD clamp 130 is configured to turn on and discharge the ESD current I4 in a reverse ESD direction from the voltage supply rail 109 (e.g., VDD) to the IO pad 108, and is referred to as a negative-to-VDD (ND) mode. In some embodiments, ESD clamp 130 is configured to turn on, after an ND mode of ESD, and discharge the ESD current I4 in the reverse ESD direction from the voltage supply rail 109 (e.g., VDD) to the IO pad 108.

In some embodiments, ESD clamp 130 is a transient clamp. For example, in some embodiments, ESD clamp 130 is configured to handle transient or rapid ESD events, e.g., rapid changes in voltage and/or current from the ESD event. During the transient or rapid ESD, the ESD clamp 130 is configured to turn on very quickly to provide a shunt path between IO pad 108 and voltage supply rail 109 (e.g., VDD) before the ESD event can cause damage to one or more elements within integrated circuit 100A or 100B. In some embodiments, ESD clamp 130 is configured to turn off slower than it turns on.

In some embodiments, ESD clamp 130 is a static clamp. In some embodiments, static clamps are configured to provide a static or steady-state voltage and current response. For example, static clamps are turned-on by a fixed voltage level.

Other types of clamp circuits, configurations and arrangements of ESD clamp 130 are within the scope of the present disclosure.

In some embodiments, ESD clamps 120 and 130 are referred to as local voltage clamp (LVC) circuits since the NS ESD mode, the PS ESD mode, the PD ESD mode and the ND ESD mode are accounted for locally, rather than being handled by other circuits where a long discharge path occurs. For example, a long discharge path in the PS/ND mode includes the header circuit 110, the power clamp 114, and the reference voltage supply VSS.

Other configurations or quantities of circuits in integrated circuit 100A are within the scope of the present disclosure.

In some embodiments, at least one of integrated circuit 100A or 100B has better ESD discharging capability and performance than other approaches while occupying less area and using less routing resources.

FIG. 1B is a schematic block diagram of an integrated circuit 100B, in accordance with some embodiments.

Integrated circuit 100B is a variation of integrated circuit 100A, and similar detailed description is therefore omitted. In comparison with integrated circuit 100A, integrated circuit 100B does not include power clamp 114, and similar detailed description is therefore omitted.

Components that are the same or similar to those in one or more of FIGS. 1A-1B, 2A-2B, 3A-3B, 4A-4B, 5A-5B, 6, 7A-7G, 8A-8D or 9 (shown below) are given the same reference numbers, and detailed description thereof is thus omitted.

Integrated circuit 100B includes internal circuit 102, voltage supply node 104, reference voltage supply node 106, IO pad 108, voltage supply rail 109, header circuit 110, power clamp 112, capacitor C1, buffer circuit 116, ESD clamp 120 and ESD clamp 130.

In some embodiments, by not including power clamp 114, integrated circuit 100B occupies less area than other approaches and using less routing resources.

In some embodiments, integrated circuit 100B is configured to achieve one or more benefits described herein including the details discussed herein.

Other configurations or quantities of circuits in integrated circuit 100B are within the scope of the present disclosure.

FIG. 2A is a circuit diagram of an integrated circuit 200A, in accordance with some embodiments.

Integrated circuit 200A is an embodiment of ESD clamp 120, and similar detailed description is therefore omitted.

Node Nd2 in FIGS. 2A, 3A, 4A and 5A corresponds to reference voltage supply node 106 of FIGS. 1A-1B.

Integrated circuit 200A includes a set of diodes 202, a resistor R1 and an NMOS transistor N1.

The set of diodes 202 is between IO pad 108 and a node Nd3.

The set of diodes 202 includes at least diode D1a, D2a or D3a coupled together in series. In some embodiments, each diode of the set of diodes 202 has a same threshold voltage. In some embodiments, at least one diode of the set of diodes 202 has a different threshold voltage from another diode of the set of diodes 202.

Each of an anode of diode D1a, IO pad 108, and a drain of NMOS transistor N1 are coupled together. In some embodiments, each of the anode of diode D1a, the IO pad 108, the drain of NMOS transistor N1 and the output of buffer circuit 116 are coupled together.

A cathode of diode D1a is coupled to an anode of diode D2a. A cathode of diode D2a is coupled to an anode of diode D3a.

Each of a cathode of diode D3a, node Nd3, a first end of resistor R1 and a gate of NMOS transistor N1 are coupled together.

In some embodiments, a current I5 flows through the set of diodes 202.

In some embodiments, one or more diodes of the set of diodes 202 is a corresponding diode coupled transistor, as shown in FIG. 6.

Other numbers of diodes or threshold voltages of the set of diodes 202 are within the scope of the present disclosure.

Resistor R1 is between a node Nd3 and the reference voltage supply node 106 (VSS). Resistor R1 has a first end and a second end.

Each of the node Nd3, the second end of resistor R1, a source of NMOS transistor N1, and the reference voltage supply node 106 (e.g., VSS) are coupled together. In some embodiments, each of the second end of resistor R1 and the source of NMOS transistor N1 are coupled to ground.

Other numbers of resistors for resistor R1 are within the scope of the present disclosure.

In some embodiments, the set of diodes 202 and resistor R1 are referred to as “an ESD detection circuit 201.”

ESD detection circuit 201 is coupled between the IO pad 108 and the reference voltage supply node 106 (or node Nd2).

ESD detection circuit 202 is configured to detect an ESD event at the IO pad 108 (e.g., an ESD current I1 or I2 in the reverse ESD direction), and to charge node Nd3 in response to the ESD event, thereby turning on NMOS transistor N1 (e.g., discharging circuit). In some embodiments, in response to being turned on, NMOS transistor N1 (e.g., discharging circuit) couples the IO pad 108 and reference voltage supply node 106 (or node Nd2), thereby providing an ESD discharge path between the IO pad 108 and reference voltage supply node 106 (or node Nd2).

NMOS transistor N1 is between the IO pad 108 and the reference voltage supply node 106.

NMOS transistor N1 is a grounded gate NMOS (ggNMOS) transistor. NMOS transistor N1 includes a gate, a drain and a source (not labelled).

In some embodiments, NMOS transistor N1 is referred to as a discharging circuit. In some embodiments, NMOS transistor N1 is configured to couple the IO pad 108 and node Nd2 during an ESD event at IO pad 108 or node Nd2, thereby providing an ESD discharge path between IO pad 108 and node Nd2. In some embodiments, a current IDS1 flows through NMOS transistor N1. In some embodiments, current IDS1 is at least one of current I1 or I2 of integrated circuit 100A-100B, and similar detailed description is therefore omitted.

In some embodiments, NMOS transistor N1 is replaced by more than one NMOS transistor. In some embodiments, NMOS transistor N1 is replaced by one or more PMOS transistors.

Other numbers of transistors or types of transistors for NMOS transistor N1 are within the scope of the present disclosure.

In some embodiments, the set of diodes 201 have a trigger voltage Vtrigger1.

In some embodiments, diode D1a has a threshold voltage Vth_d1a, diode D2a has a threshold voltage Vth_d2a and diode D3a has a threshold voltage Vth_d3a. In some embodiments, the trigger voltage Vtrigger1 is equal to the sum of the threshold voltage (e.g., Vth_d1a+Vth_d2a+Vth_d3a) of each diode in the set of diodes 202.

In some embodiments, where each diode in the set of diodes 202 has a substantially equal threshold voltage (e.g., Vth_d1a), then the trigger voltage Vtrigger1 is equal to the number of diodes (e.g., 3) in the set of diodes 202 multiplied by the threshold voltage (e.g., 3*Vth_d1a) of each diode in the set of diodes 202.

In some embodiments, the set of diodes 201 is turned on when a voltage of an ESD event V_{ESD} is greater than the trigger voltage Vtrigger1, and thus integrated circuit 200A is configured to operate in an ESD mode where the ESD event is discharged by NMOS transistor N1. For example, when an ESD event (e.g., PS mode) at IO pad 108 occurs (e.g., ESD current I1 or I2 in the reverse ESD direction), the ESD current or voltage at node Nd1 rises rapidly. In some embodiments, if the ESD voltage is greater than the trigger voltage of the set of diodes 202, then the set of diodes 202 turn on or become forward biased. In response to where the set of diodes 202 turn on or become forward biased, the voltage of node Nd3 (e.g., across resistor R1) is caused to rise rapidly. In response to the rapidly rising voltage at node Nd3, the gate of NMOS transistor N1 is charged by ESD detection circuit 201. In response to being charged by ESD detection circuit 201, NMOS transistor N1 of a discharging circuit is turned on and couples IO pad 108 to node Nd2. By being turned on and coupling node IO pad 108 to node Nd2, the channel of NMOS transistor N1 discharges the ESD current I2 in the reverse ESD direction from IO pad 108 to node Nd2.

In some embodiments, the set of diodes 201 is turned off when a voltage of an ESD event V_{ESD} is less than or equal to the trigger voltage Vtrigger1, and thus integrated circuit 200A is configured to operate in a Normal mode where no ESD event occurs, and therefore NMOS transistor N1 is turned off. For example, when no ESD event (e.g., Normal mode) at IO pad 108 occurs, the voltage at the IO pad 108 is less than the trigger voltage of the set of diodes 202, thereby causing the set of diodes 202 to be turned off. In response to where the set of diodes 202 is turned off, the voltage of node Nd3 is not sufficient to turn on NMOS transistor N1. In some embodiments, in response to NMOS transistor N1 being turned off, IO pad 108 and node Nd2 are electrically decoupled from each other. In some embodiments, NMOS transistor N1 is turned off when the voltage of node Nd3 is substantially equal to 0 V.

In some embodiments, a resistance of resistor R1 varies from process, voltage and/or temperature (PVT) variations. In some embodiments, integrated circuit 200A is able to overcome resistance variations of R1 by being a self-bias adjusting circuit thereby resulting in a more flexible design with better performance than other approaches.

For example, in some embodiments, any fluctuation of the gate to source voltage V_{GS} of NMOS transistor N1 induced by the resistance variation of resistor R1 is self-compensated. In some embodiments, as the resistance of resistor R1 increases, then the gate to source voltage V_{GS} of NMOS transistor N1 initially increases, which causes the voltage Vout of the IO pad 108 to decrease. In some embodiments, by decreasing the voltage Vout of the IO pad 108 causes the current I5 to decrease, which thereby causes the gate to source voltage V_{GS} of NMOS transistor N1 to decrease. Thus, by using integrated circuit 200A, increases in the resistance of resistor R1 thereby results in a self-compensating decrease in the gate to source voltage V_{GS} of NMOS transistor N1.

In yet another example, in some embodiments, as the resistance of resistor R1 decreases, then the gate to source voltage V_{GS} of NMOS transistor N1 initially decreases, which causes the voltage Vout of the IO pad 108 to increase. In some embodiments, by increasing the voltage Vout of the IO pad 108 causes the current I5 to increase, which thereby causes the gate to source voltage V_{GS} of NMOS transistor N1 to increase. Thus, by using integrated circuit 200A, decreases in the resistance of resistor R1 thereby results in a self-compensating increase in the gate to source voltage V_{GS} of NMOS transistor N1.

Other types of circuits, configurations and arrangements of the set of diodes 202, resistor R1 or NMOS transistor N1 are within the scope of the present disclosure.

In some embodiments, integrated circuit 200A is configured to achieve one or more benefits described herein including the details discussed herein.

Other configurations or quantities of circuits in integrated circuit 200A are within the scope of the present disclosure.

FIG. 2B is a circuit diagram of an integrated circuit 200B, in accordance with some embodiments.

Integrated circuit 200B is an embodiment of ESD clamp 130, and similar detailed description is therefore omitted.

In some embodiments, a node Nd1 of FIGS. 2B, 3B, 4B and 5B corresponds to voltage supply node 104 of FIGS. 1A-1B or voltage supply rail 109 (e.g. VDD).

Integrated circuit 200B includes a set of diodes 212, a resistor R2 and a PMOS transistor P1.

The set of diodes 212 is between IO pad 108 and a node Nd4.

The set of diodes 212 includes at least diode D1b, D2b or D3b coupled together in series. In some embodiments, each diode of the set of diodes 212 has a same threshold voltage. In some embodiments, at least one diode of the set of diodes 212 has a different threshold voltage from another diode of the set of diodes 212.

Each of an anode of diode D1b, node Nd4, a first end of resistor R2 and a gate of PMOS transistor P1 are coupled together.

A cathode of diode D1b is coupled to an anode of diode D2b. A cathode of diode D2b is coupled to an anode of diode D3b.

Each of an anode of diode D3b, IO pad 108, and a drain of PMOS transistor P1 are coupled together. In some embodiments, each of the anode of diode D3b, the IO pad 108, the drain of PMOS transistor P1 and the output of buffer circuit 116 are coupled together. In some embodiments, each of the anode of diode D3b, the IO pad 108, the drain of PMOS transistor P1, the anode of diode D1a, the drain of NMOS transistor N1 and the output of buffer circuit 116 are coupled together.

In some embodiments, a current I6 flows through the set of diodes 212.

In some embodiments, one or more diodes of the set of diodes 212 is a corresponding diode coupled transistor, as shown in FIG. 6.

Other numbers of diodes or threshold voltages of the set of diodes 212 are within the scope of the present disclosure.

Resistor R2 is between a node Nd4 and the voltage supply rail 109 (e.g. VDD). Resistor R2 has a first end and a second end.

Each of the node Nd4, the second end of resistor R2, a source of PMOS transistor P1, and the voltage supply rail 109 (e.g. VDD) are coupled together. In some embodiments, each of the second end of resistor R2 and the source of PMOS transistor P1 are coupled to a voltage supply VDD.

Other numbers of resistors for resistor R2 are within the scope of the present disclosure.

In some embodiments, the set of diodes 212 and resistor R2 are referred to as “an ESD detection circuit 211.”

ESD detection circuit 211 is coupled between the IO pad 108 and the voltage supply rail 109 (or node Nd1).

ESD detection circuit 212 is configured to detect an ESD event at the IO pad 108 (e.g., an ESD current I3 or I4 in the reverse ESD direction), and to charge node Nd4 in response to the ESD event, thereby turning on PMOS transistor P1 (e.g., discharging circuit). In some embodiments, in response to being turned on, PMOS transistor P1 (e.g., discharging circuit) couples the IO pad 108 and voltage supply rail 109 (or node Nd1), thereby providing an ESD discharge path between the IO pad 108 and voltage supply rail 109 (or node Nd1).

PMOS transistor P1 is between the IO pad 108 and the voltage supply rail 109.

PMOS transistor P1 is a grounded gate PMOS (ggPMOS) transistor. PMOS transistor P1 includes a gate, a drain and a source (not labelled).

In some embodiments, PMOS transistor P1 is referred to as a discharging circuit. In some embodiments, PMOS transistor P1 is configured to couple the IO pad 108 and node Nd1 during an ESD event at IO pad 108 or node Nd1, thereby providing an ESD discharge path between IO pad 108 and node Nd1. In some embodiments, a current IDS2 flows through PMOS transistor P1. In some embodiments, current IDS2 is at least one of current I3 or I4 of integrated circuit 100A-100B, and similar detailed description is therefore omitted.

In some embodiments, PMOS transistor P1 is replaced by more than one PMOS transistor. In some embodiments, PMOS transistor P1 is replaced by one or more NMOS transistors.

Other numbers of transistors or types of transistors for PMOS transistor P1 are within the scope of the present disclosure.

In some embodiments, the set of diodes 211 have a trigger voltage Vtrigger2.

In some embodiments, diode D1b has a threshold voltage Vth_D1b, diode D2b has a threshold voltage Vth_D2b and diode D3b has a threshold voltage Vth_D3b. In some embodiments, the trigger voltage Vtrigger2 is equal to the sum of the threshold voltage (e.g., Vth_D1b+Vth_D2b+Vth_D3b) of each diode in the set of diodes 212.

In some embodiments, where each diode in the set of diodes 212 has a substantially equal threshold voltage (e.g., Vth_D1b), then the trigger voltage Vtrigger2 is equal to the number of diodes (e.g., 3) in the set of diodes 212 multiplied by the threshold voltage (e.g., 3*Vth_D1b) of each diode in the set of diodes 212.

In some embodiments, the set of diodes 211 is turned on when a voltage of an ESD event V_{ESD} is greater than the trigger voltage Vtrigger2, and thus integrated circuit 200B is configured to operate in an ESD mode where the ESD event is discharged by PMOS transistor P1. For example, when an ESD event (e.g., ND mode) at IO pad 108 occurs (e.g., ESD current I3 or I4 in the reverse ESD direction), the ESD current or voltage at node Nd1 rises rapidly. In some embodiments, if the ESD voltage is greater than the trigger voltage of the set of diodes 212, then the set of diodes 212 turn on or become forward biased. In response to where the set of diodes 212 turn on or become forward biased, the voltage of node Nd4 (e.g., across resistor R2) is caused to rise rapidly. In response to the rapidly rising voltage at node Nd4, the gate of PMOS transistor P1 is charged by ESD detection circuit 211. In response to being charged by ESD detection circuit 211, PMOS transistor P1 of a discharging circuit is turned on and couples IO pad 108 to node Nd1. By being turned on and coupling node IO pad 108 to node Nd1, the channel of PMOS transistor P1 discharges the ESD current I2 in the reverse ESD direction from node Nd1 to IO pad 108.

In some embodiments, the set of diodes 211 is turned off when a voltage of an ESD event V_{ESD} is less than or equal to the trigger voltage Vtrigger2, and thus integrated circuit 200B is configured to operate in a Normal mode where no ESD event occurs, and therefore PMOS transistor P1 is turned off. For example, when no ESD event (e.g., Normal mode) at IO pad 108 occurs, the voltage at the IO pad 108 is less than the trigger voltage of the set of diodes 212, thereby causing the set of diodes 212 to be turned off. In response to where the set of diodes 212 is turned off, the voltage of node Nd4 is not sufficient to turn on PMOS transistor P1. In some embodiments, in response to PMOS transistor P1 being turned off, IO pad 108 and node Nd1 are electrically decoupled from each other.

In some embodiments, a resistance of resistor R2 varies from PVT variations. In some embodiments, integrated circuit 200B is able to overcome resistance variations of R2 by being a self-bias adjusting circuit thereby resulting in a more flexible design with better performance than other approaches.

For example, in some embodiments, any fluctuation of the gate to source voltage V_{GS} of PMOS transistor P1 induced by the resistance variation of resistor R2 is self-compensated. In some embodiments, as the resistance of resistor R2 increases, then the gate to source voltage V_{GS} of PMOS transistor P1 initially increases, which causes the voltage Vout of the IO pad 108 to decrease. In some embodiments, by decreasing the voltage Vout of the IO pad 108 causes the current I6 to decrease, which thereby causes the gate to source voltage V_{GS} of PMOS transistor P1 to decrease. Thus, by using integrated circuit 200B, increases in the resistance of resistor R2 thereby results in a self-compensating decrease in the gate to source voltage V_{GS} of PMOS transistor P1.

In yet another example, in some embodiments, as the resistance of resistor R2 decreases, then the gate to source voltage V_{GS} of PMOS transistor P1 initially decreases, which causes the voltage Vout of the IO pad 108 to increase. In some embodiments, by increasing the voltage Vout of the IO pad 108 causes the current I6 to increase, which thereby causes the gate to source voltage V_{GS} of PMOS transistor P1 to increase. Thus, by using integrated circuit 200B, decreases in the resistance of resistor R2 thereby results in a self-compensating increase in the gate to source voltage V_{GS} of PMOS transistor P1.

Other types of circuits, configurations and arrangements of the set of diodes 212, resistor R2 or PMOS transistor P1 are within the scope of the present disclosure.

In some embodiments, integrated circuit 200B is configured to achieve one or more benefits described herein including the details discussed herein.

Other configurations or quantities of circuits in integrated circuit 200B are within the scope of the present disclosure.

FIG. 3A is a circuit diagram of an integrated circuit 300A, in accordance with some embodiments.

Integrated circuit 300A is an embodiment of ESD clamp 120, and similar detailed description is therefore omitted.

Integrated circuit 300A is a variation of integrated circuit 200A of FIG. 2A, and similar detailed description is therefore omitted. In comparison with integrated circuit 200A, integrated circuit 300A further includes diode D4a, and similar detailed description is therefore omitted.

Integrated circuit 300A includes the set of diodes 202, the resistor R1, NMOS transistor N1 and a diode D4a.

Diode D4a is between the IO pad 108 and the drain of NMOS transistor N1. In comparison with integrated circuit 200A of FIG. 2A, NMOS transistor N1 of FIG. 3A is between a cathode of diode D4a and the reference voltage supply node 106 (or node Nd2).

In FIG. 3A, each of an anode of diode D4a, the anode of diode D1a and IO pad 108 are coupled together. In some embodiments, each of the anode of diode D4a, the anode of diode D1a, IO pad 108 and the output of buffer circuit 116 are coupled together.

A cathode of diode D4a is coupled to the drain of NMOS transistor N1.

In some embodiments, diode D4a has a threshold voltage Vth_D4a.

In some embodiments, the current IDS2 flows through at least one of diode D4a or PMOS transistor P1. In some embodiments, current IDS2 is at least one of current I3 or I4 of integrated circuit 100A-100B, and similar detailed description is therefore omitted.

In some embodiments, one or more diodes of the set of diodes 202 or diode D4a is a corresponding diode coupled transistor, as shown in FIG. 6.

Other numbers of diodes or threshold voltages of the set of diodes 202 or diode D4a are within the scope of the present disclosure.

In some embodiments, diode D4a is configured to provide protection of NMOS transistor N1 during an ESD event at IO pad 108 or node Nd2. For example, when an ESD event occurs at IO pad 108 or node Nd2, diode D4a is configured to provide a voltage drop (e.g., equal to the threshold voltage of diode D4a) that lowers the voltage of the ESD event V_{ESD} applied across the NMOS transistor N1 (e.g., V_{ESD}−Vth_4a) thereby reducing the ESD stress across the NMOS transistor N1, thus providing protection of the NMOS transistor N1.

In some embodiments, descriptions for when an ESD event occurs at node Nd2 (e.g., ESD current I1 or I3 in the reverse ESD direction) with ESD detection circuit 201 for FIG. 3A is similar to the description of when an ESD event occurs at node Nd2 for ESD detection circuit 201 of FIG. 2A, and similar detailed description is therefore omitted for brevity.

Other types of circuits, configurations and arrangements of the diode D4a, the set of diodes 202, resistor R1 or NMOS transistor N1 are within the scope of the present disclosure.

In some embodiments, integrated circuit 300A is configured to achieve one or more benefits described herein including the details discussed herein.

Other configurations or quantities of circuits in integrated circuit 300A are within the scope of the present disclosure.

FIG. 3B is a circuit diagram of an integrated circuit 300B, in accordance with some embodiments.

Integrated circuit 300B is an embodiment of ESD clamp 130, and similar detailed description is therefore omitted.

Integrated circuit 300B is a variation of integrated circuit 200B of FIG. 2B, and similar detailed description is therefore omitted. In comparison with integrated circuit 200B, integrated circuit 300B further includes diode D4b, and similar detailed description is therefore omitted.

Integrated circuit 300B includes the set of diodes 212, the resistor R2, PMOS transistor P1 and a diode D4b.

Diode D4b is between the IO pad 108 and the drain of PMOS transistor P1. In comparison with integrated circuit 200B of FIG. 2B, PMOS transistor P1 of FIG. 3B is between an anode of diode D4b and the IO pad 108.

In FIG. 3B, an anode of diode D4b is coupled to the drain of PMOS transistor P1.

In FIG. 3B, each of a cathode of diode D4b, the cathode of diode D3b and IO pad 108 are coupled together. In some embodiments, each of the cathode of diode D4b, the cathode of diode D3b, IO pad 108 and the output of buffer circuit 116 are coupled together. In some embodiments, each of the cathode of diode D4b, the cathode of diode D3b, IO pad 108, the anode of diode D4a, the anode of diode D1a and the output of buffer circuit 116 are coupled together.

In some embodiments, diode D4b has a threshold voltage Vth_D4b.

In some embodiments, the current IDS2 flows through at least one of diode D4b or PMOS transistor P1. In some embodiments, current IDS2 is at least one of current I3 or I4 of integrated circuit 100A-100B, and similar detailed description is therefore omitted.

In some embodiments, one or more diodes of the set of diodes 212 or diode D4b is a corresponding diode coupled transistor, as shown in FIG. 6.

Other numbers of diodes or threshold voltages of the set of diodes 212 or diode D4b are within the scope of the present disclosure.

In some embodiments, diode D4b is configured to provide protection of PMOS transistor P1 during an ESD event at IO pad 108 or node Nd1. For example, when an ESD event occurs at IO pad 108 or node Nd1, diode D4b is configured to provide a voltage drop (e.g., equal to the threshold voltage of diode D4b) that lowers the voltage of the ESD event V_{ESD} applied across the PMOS transistor P1 (e.g., V_{ESD}−Vth_4b) thereby reducing the ESD stress across the PMOS transistor P1, thus providing protection of the PMOS transistor P1.

In some embodiments, descriptions for when an ESD event occurs at node Nd1 (e.g., ESD current I2 or I4 in the reverse ESD direction) with ESD detection circuit 211 for FIG. 3B is similar to the description of when an ESD event occurs at node Nd1 for ESD detection circuit 211 of FIG. 2B, and similar detailed description is therefore omitted for brevity.

Other types of circuits, configurations and arrangements of the diode D4b, the set of diodes 212, resistor R2 or PMOS transistor P1 are within the scope of the present disclosure.

In some embodiments, integrated circuit 300B is configured to achieve one or more benefits described herein including the details discussed herein.

Other configurations or quantities of circuits in integrated circuit 300B are within the scope of the present disclosure.

FIG. 4A is a circuit diagram of an integrated circuit 400A, in accordance with some embodiments.

Integrated circuit 400A is an embodiment of ESD clamp 120, and similar detailed description is therefore omitted.

Integrated circuit 400A is a variation of integrated circuit 300A of FIG. 3A, and similar detailed description is therefore omitted. In comparison with integrated circuit 300A, integrated circuit 400A further includes diode D5a, and similar detailed description is therefore omitted.

In comparison with integrated circuit 300A, a set of diodes 402 replaces the set of diodes 202 of FIG. 3A, and similar detailed description is therefore omitted.

In comparison with integrated circuit 300A, an ESD detection circuit 402 replaces the ESD detection circuit 202 of FIG. 3A, and similar detailed description is therefore omitted.

Integrated circuit 400A includes a set of diodes 402, the resistor R1, NMOS transistor N1 and the diode D4a.

The set of diodes 402 includes at least diode D1a, D2a, D3a or D5a coupled together in series. In some embodiments, each diode of the set of diodes 402 has a same threshold voltage. In some embodiments, at least one diode of the set of diodes 402 has a different threshold voltage from another diode of the set of diodes 402.

In FIG. 4A, the cathode of diode D3a is coupled to an anode of diode D5a.

In FIG. 4A, each of a cathode of diode D5a, node Nd3, the first end of resistor R1 and the gate of NMOS transistor N1 are coupled together.

In some embodiments, current I5 flows through the set of diodes 402.

In some embodiments, one or more diodes of the set of diodes 402 or diode D4a is a corresponding diode coupled transistor, as shown in FIG. 6.

Other numbers of diodes or threshold voltages of the set of diodes 402 or diode D4a are within the scope of the present disclosure.

In some embodiments, the set of diodes 402 and resistor R1 are referred to as “an ESD detection circuit 401.”

ESD detection circuit 401 is coupled between the IO pad 108 and the reference voltage supply node 106 (or node Nd2).

ESD detection circuit 402 is configured to detect an ESD event at the IO pad 108 (e.g., an ESD current I1 or I2 in the reverse ESD direction), and to charge node Nd3 in response to the ESD event, thereby turning on NMOS transistor N1 (e.g., discharging circuit). In some embodiments, in response to being turned on, NMOS transistor N1 (e.g., discharging circuit) couples the IO pad 108 and reference voltage supply node 106 (or node Nd2), thereby providing an ESD discharge path between the IO pad 108 and reference voltage supply node 106 (or node Nd2).

In some embodiments, the set of diodes 401 have a trigger voltage Vtrigger3.

In some embodiments, diode D5a has a threshold voltage Vth_d5a. In some embodiments, the trigger voltage Vtrigger3 is equal to the sum of the threshold voltage (e.g., Vth_d1a+Vth_d2a+Vth_d3a+Vth_d5a) of each diode in the set of diodes 402.

In some embodiments, where each diode in the set of diodes 402 has a substantially equal threshold voltage (e.g., Vth_d1a), then the trigger voltage Vtrigger3 is equal to the number of diodes (e.g., 4) in the set of diodes 402 multiplied by the threshold voltage (e.g., 4*Vth_d1a) of each diode in the set of diodes 402.

In some embodiments, the set of diodes 401 is turned on when a voltage of an ESD event V_{ESD} is greater than the trigger voltage Vtrigger3, and thus integrated circuit 400A is configured to operate in an ESD mode where the ESD event is discharged by NMOS transistor N1. For example, when an ESD event (e.g., PS mode) at IO pad 108 occurs (e.g., ESD current I1 or I2 in the reverse ESD direction), the ESD current or voltage at node Nd1 rises rapidly. In some embodiments, if the ESD voltage is greater than the trigger voltage of the set of diodes 402, then the set of diodes 402 turn on or become forward biased. In response to where the set of diodes 402 turn on or become forward biased, the voltage of node Nd3 (e.g., across resistor R1) is caused to rise rapidly. In response to the rapidly rising voltage at node Nd3, the gate of NMOS transistor N1 is charged by ESD detection circuit 401. In response to being charged by ESD detection circuit 401, NMOS transistor N1 of a discharging circuit is turned on and couples IO pad 108 to node Nd2. By being turned on and coupling node IO pad 108 to node Nd2, the channel of NMOS transistor N1 discharges the ESD current I2 in the reverse ESD direction from IO pad 108 to node Nd2.

In some embodiments, the set of diodes 401 is turned off when a voltage of an ESD event V_{ESD} is less than or equal to the trigger voltage Vtrigger3, and thus integrated circuit 400A is configured to operate in a Normal mode where no ESD event occurs, and therefore NMOS transistor N1 is turned off. For example, when no ESD event (e.g., Normal mode) at IO pad 108 occurs, the voltage at the IO pad 108 is less than the trigger voltage of the set of diodes 402, thereby causing the set of diodes 402 to be turned off. In response to where the set of diodes 402 is turned off, the voltage of node Nd3 is not sufficient to turn on NMOS transistor N1. In some embodiments, in response to NMOS transistor N1 being turned off, IO pad 108 and node Nd2 are electrically decoupled from each other. In some embodiments, NMOS transistor N1 is turned off when the voltage of node Nd3 is substantially equal to 0 V.

In some embodiments, diode D5a is configured to provide protection of NMOS transistor N1 during an ESD event at IO pad 108 or node Nd2 similar to the details provided in FIG. 3A, and similar detailed description is therefore omitted.

In some embodiments, by including diode D5a in the set of diodes 402 thereby causes the trigger voltage Vtrigger3 of the set of diodes 402 to be increased by the threshold voltage Vth_d5a of diode D5a. In some embodiments, by increasing the trigger voltage Vtrigger3 of the set of diodes 402, the set of diodes are turned on by a higher trigger voltage Vtrigger3 than that without the set of diodes 402 during an ESD event at IO pad 108 or node Nd2, or during no ESD event (e.g., Normal mode) at IO pad 108.

In some embodiments, during a normal operation (e.g., Non-ESD mode), by configuring the set of diodes 402 to be turned on by a higher trigger voltage Vtrigger3 compared to other approaches, thereby causes the leakage current from the set of diodes 402 to be lowered compared to other approaches. For example, in some embodiments, the voltage Vout of the IO pad 108 is distributed across 4 diodes (e.g., diodes D1 a, D2 a, D3 a and D5 a), thus the voltage across each diode of the set of diodes 402 is lower than approaches where the voltage Vout of the IO pad 108 is distributed across less diodes, thereby lowering the leakage current from the set of diodes 402 compared to other approaches.

In some embodiments, by increasing the trigger voltage Vtrigger3 of the set of diodes 402, the set of diodes 402 are turned on by a higher trigger voltage Vtrigger3 during an ESD event at IO pad 108 or node Nd2, thereby increasing a voltage of the ESD event V_{ESD} at IO pad 108 or node Nd2.

In some embodiments, by increasing the trigger voltage Vtrigger3 of the set of diodes 402, causes a voltage V_{ESD} of an ESD event at IO pad 108 or node Nd2 to be increased before integrated circuit 400A is configured to discharge the ESD current. However, increasing the voltage V_{ESD} of an ESD event at IO pad 108 or node Nd2 could also cause ESD stress of NMOS transistor N1 when additional protection is not provided to NMOS transistor N1.

As described with respect to at least FIG. 3A, diode D4a is configured to provide protection of the NMOS transistor N1 by reducing the ESD stress across the NMOS transistor N1. For example, when an ESD event occurs at IO pad 108 or node Nd2, diode D4a is configured to provide a voltage drop (e.g., equal to the threshold voltage of diode D4a) that lowers the voltage of the ESD event V_{ESD} applied across the NMOS transistor N1 (e.g., V_{ESD}−Vth_4a) thereby reducing the ESD stress across the NMOS transistor N1, thus providing protection of the NMOS transistor N1. Thus, the inclusion of diode D4a in integrated circuit 400A counteracts the increased voltage of the ESD event V_{ESD} that is from the higher trigger voltage Vtrigger3 of the set of diodes 402, thereby reducing the ESD stress across the NMOS transistor N1.

In some embodiments, integrated circuit 400A can be modified by including additional diodes in the set of diodes 402. In some embodiments, for each additional diode that is included in the set of diodes 402, a corresponding additional diode is included between the diode D4a and NMOS transistor N1. For example, in some embodiments, if one additional diode was included in the set of diodes 402, then one additional diode would be included between diode D4a and NMOS transistor N1. For example, in some embodiments, if two additional diodes were included in the set of diodes 402, then two additional diodes would be included between diode D4a and NMOS transistor N1. Other numbers of diodes in the set of diodes 402 or between the diode D4a and NMOS transistor N1 are within the scope of the present disclosure.

Other types of circuits, configurations and arrangements of the diode D5a, the set of diodes 402, resistor R1 or NMOS transistor N1 are within the scope of the present disclosure.

In some embodiments, integrated circuit 400A is configured to achieve one or more benefits described herein including the details discussed herein.

Other configurations or quantities of circuits in integrated circuit 400A are within the scope of the present disclosure.

FIG. 4B is a circuit diagram of an integrated circuit 400B, in accordance with some embodiments.

Integrated circuit 400B is an embodiment of ESD clamp 130, and similar detailed description is therefore omitted.

Integrated circuit 400B is a variation of integrated circuit 300B of FIG. 3B, and similar detailed description is therefore omitted. In comparison with integrated circuit 300B, integrated circuit 400B further includes diode D5b, and similar detailed description is therefore omitted.

In comparison with integrated circuit 300B, a set of diodes 412 replaces the set of diodes 202 of FIG. 3B, and similar detailed description is therefore omitted.

In comparison with integrated circuit 300B, an ESD detection circuit 412 replaces the ESD detection circuit 212 of FIG. 3B, and similar detailed description is therefore omitted.

Integrated circuit 400B includes a set of diodes 412, the resistor R2, PMOS transistor P1 and the diode D4b.

The set of diodes 412 includes at least diode D1b, D2b, D3b or D5b coupled together in series. In some embodiments, each diode of the set of diodes 412 has a same threshold voltage. In some embodiments, at least one diode of the set of diodes 412 has a different threshold voltage from another diode of the set of diodes 412.

In FIG. 4B, the cathode of diode D3b is coupled to an anode of diode D5b.

In FIG. 4B, each of a cathode of diode D5b, node Nd4, the first end of resistor R2 and the gate of PMOS transistor P1 are coupled together.

In some embodiments, current I6 flows through the set of diodes 412.

In some embodiments, one or more diodes of the set of diodes 412 or diode D4b is a corresponding diode coupled transistor, as shown in FIG. 6.

Other numbers of diodes or threshold voltages of the set of diodes 412 or diode D4b are within the scope of the present disclosure.

In some embodiments, the set of diodes 412 and resistor R2 are referred to as “an ESD detection circuit 411.”

ESD detection circuit 411 is coupled between the IO pad 108 and the voltage supply rail 109 (or node Nd1).

ESD detection circuit 412 is configured to detect an ESD event at the IO pad 108 (e.g., an ESD current I3 or I4 in the reverse ESD direction), and to charge node Nd4 in response to the ESD event, thereby turning on PMOS transistor P1 (e.g., discharging circuit). In some embodiments, in response to being turned on, PMOS transistor P1 (e.g., discharging circuit) couples the IO pad 108 and voltage supply rail 109 (or node Nd1), thereby providing an ESD discharge path between the IO pad 108 and voltage supply rail 109 (or node Nd1).

In some embodiments, the set of diodes 411 have a trigger voltage Vtrigger4.

In some embodiments, diode D5b has a threshold voltage Vth_d5b. In some embodiments, the trigger voltage Vtrigger4 is equal to the sum of the threshold voltage (e.g., Vth_d1b+Vth_d2b+Vth_d3b+Vth_d5b) of each diode in the set of diodes 412.

In some embodiments, where each diode in the set of diodes 412 has a substantially equal threshold voltage (e.g., Vth_d1b), then the trigger voltage Vtrigger4 is equal to the number of diodes (e.g., 4) in the set of diodes 412 multiplied by the threshold voltage (e.g., 4*Vth_d1b) of each diode in the set of diodes 412.

In some embodiments, the set of diodes 411 is turned on when a voltage of an ESD event V_{ESD} is greater than the trigger voltage Vtrigger4, and thus integrated circuit 400B is configured to operate in an ESD mode where the ESD event is discharged by PMOS transistor P1. For example, when an ESD event (e.g., ND mode) at IO pad 108 occurs (e.g., ESD current I3 or I4 in the reverse ESD direction), the ESD current or voltage at node Nd1 rises rapidly. In some embodiments, if the ESD voltage is greater than the trigger voltage of the set of diodes 412, then the set of diodes 412 turn on or become forward biased. In response to where the set of diodes 412 turn on or become forward biased, the voltage of node Nd4 (e.g., across resistor R2) is caused to rise rapidly. In response to the rapidly rising voltage at node Nd4, the gate of PMOS transistor P1 is charged by ESD detection circuit 411. In response to being charged by ESD detection circuit 411, PMOS transistor P1 of a discharging circuit is turned on and couples IO pad 108 to node Nd1. By being turned on and coupling node IO pad 108 to node Nd1, the channel of PMOS transistor P1 discharges the ESD current I4 in the reverse ESD direction from IO pad 108 to node Nd1.

In some embodiments, the set of diodes 411 is turned off when a voltage of an ESD event V_{ESD} is less than or equal to the trigger voltage Vtrigger4, and thus integrated circuit 400B is configured to operate in a Normal mode where no ESD event occurs, and therefore PMOS transistor P1 is turned off. For example, when no ESD event (e.g., Normal mode) at IO pad 108 occurs, the voltage at the IO pad 108 is less than the trigger voltage of the set of diodes 412, thereby causing the set of diodes 412 to be turned off. In response to where the set of diodes 412 is turned off, the voltage of node Nd4 is not sufficient to turn on PMOS transistor P1. In some embodiments, in response to PMOS transistor P1 being turned off, IO pad 108 and node Nd1 are electrically decoupled from each other.

In some embodiments, diode D5b is configured to provide protection of PMOS transistor P1 during an ESD event at IO pad 108 or node Nd1 similar to the details provided in FIG. 3B, and similar detailed description is therefore omitted.

In some embodiments, by including diode D5b in the set of diodes 412 thereby causes the trigger voltage Vtrigger4 of the set of diodes 412 to be increased by the threshold voltage Vth_D5b of diode D5b. In some embodiments, by increasing the trigger voltage Vtrigger4 of the set of diodes 412, the set of diodes are turned on by a higher trigger voltage Vtrigger4 than that without the set of diodes 412 during an ESD event at IO pad 108 or node Nd1, or during no ESD event (e.g., Normal mode) at IO pad 108.

In some embodiments, during a normal operation (e.g., Non-ESD mode), by configuring the set of diodes 412 to be turned on by a higher trigger voltage Vtrigger4 compared to other approaches, thereby causes the leakage current from the set of diodes 412 to be lowered compared to other approaches. For example, in some embodiments, the voltage Vout of the IO pad 108 is distributed across 4 diodes (e.g., diodes D1b, D2b, D3b and D5b), thus the voltage across each diode of the set of diodes 412 is lower than approaches where the voltage Vout of the IO pad 108 is distributed across less diodes, thereby lowering the leakage current from the set of diodes 412 compared to other approaches.

In some embodiments, by increasing the trigger voltage Vtrigger4 of the set of diodes 412, the set of diodes 412 are turned on by a higher trigger voltage Vtrigger4 during an ESD event at IO pad 108 or node Nd1, thereby increasing a voltage of the ESD event V_{ESD} at IO pad 108 or node Nd1.

In some embodiments, by increasing the trigger voltage Vtrigger4 of the set of diodes 412, causes a voltage V_{ESD} of an ESD event at IO pad 108 or node Nd1 to be increased before integrated circuit 400B is configured to discharge the ESD current. However, increasing the voltage V_{ESD} of an ESD event at IO pad 108 or node Nd1 could also cause ESD stress of PMOS transistor P1 when additional protection is not provided to PMOS transistor P1.

As described with respect to at least FIG. 3B, diode D4b is configured to provide protection of the PMOS transistor P1 by reducing the ESD stress across the PMOS transistor P1. For example, when an ESD event occurs at IO pad 108 or node Nd1, diode D4b is configured to provide a voltage drop (e.g., equal to the threshold voltage of diode D4b) that lowers the voltage of the ESD event V_{ESD} applied across the PMOS transistor P1 (e.g., V_{ESD}−Vth_4b) thereby reducing the ESD stress across the PMOS transistor P1, thus providing protection of the PMOS transistor P1. Thus, the inclusion of diode D4b in integrated circuit 400B counteracts the increased voltage of the ESD event V_{ESD} that is from the higher trigger voltage Vtrigger4 of the set of diodes 412, thereby reducing the ESD stress across the PMOS transistor P1.

In some embodiments, integrated circuit 400B can be modified by including additional diodes in the set of diodes 412. In some embodiments, for each additional diode that is included in the set of diodes 412, a corresponding additional diode is included between the diode D4b and PMOS transistor P1. For example, in some embodiments, if one additional diode was included in the set of diodes 412, then one additional diode would be included between diode D4b and PMOS transistor P1. For example, in some embodiments, if two additional diodes were included in the set of diodes 412, then two additional diodes would be included between diode D4b and PMOS transistor P1. Other numbers of diodes in the set of diodes 412 or between the diode D4b and PMOS transistor P1 are within the scope of the present disclosure.

Other types of circuits, configurations and arrangements of the diode D5b, the set of diodes 412, resistor R2 or PMOS transistor P1 are within the scope of the present disclosure.

In some embodiments, integrated circuit 400B is configured to achieve one or more benefits described herein including the details discussed herein.

Other configurations or quantities of circuits in integrated circuit 400B are within the scope of the present disclosure.

FIG. 5A is a circuit diagram of an integrated circuit 500A, in accordance with some embodiments.

Integrated circuit 500A is an embodiment of ESD clamp 120, and similar detailed description is therefore omitted.

Integrated circuit 500A is a variation of integrated circuit 400A of FIG. 4A, and similar detailed description is therefore omitted. In comparison with integrated circuit 400A, integrated circuit 500A further includes a PMOS transistor P3 and an NMOS transistor N2, and similar detailed description is therefore omitted.

In comparison with integrated circuit 400A, a PMOS transistor P2 replaces diode D1a of FIG. 4A, and similar detailed description is therefore omitted. In some embodiments, PMOS transistor P2 is a diode-coupled transistor 504, and operation of PMOS transistor P2 is similar to the diode D1a of FIG. 4A, and similar detailed description is therefore omitted.

Integrated circuit 500A includes a set of diodes 502, the resistor R1, NMOS transistor N1, NMOS transistor N2, PMOS transistor P2, PMOS transistor P3 and the diode D4a.

The set of diodes 502 is a variation of the set of diodes 402 of FIG. 4A, and similar detailed description is therefore omitted. In comparison with the set of diodes 402, the set of diodes 502 does not include diode D1a, and similar detailed description is therefore omitted.

In some embodiments, one or more diodes of the set of diodes 502 or diode D4a is a corresponding diode coupled transistor, as shown in FIG. 6.

Other numbers of diodes or threshold voltages of the set of diodes 502 or diode D4a are within the scope of the present disclosure.

PMOS transistor P2 is coupled between IO pad 108 and the anode of diode D2a. PMOS transistor P2 is a diode-coupled transistor 504.

Each of a gate of PMOS transistor P2, a drain of PMOS transistor P2, a gate of PMOS transistor P3, and the anode of diode D2a are coupled to each other.

In FIG. 5A, each of a source of PMOS transistor P2, a source of PMOS transistor P3, the anode of diode D4a and the IO pad 108 are coupled to each other.

PMOS transistor P3 is coupled between IO pad 108 and a drain of NMOS transistor N2.

Each of a drain of PMOS transistor P3 and the drain of NMOS transistor N2 are coupled to each other.

NMOS transistor N2 is coupled between PMOS transistor P3 and the reference voltage supply node 106 (or node Nd2).

Each of a source of NMOS transistor N2, the source of NMOS transistor N1, the second end of resistor R1 and the reference voltage supply node 106 (or node Nd2) are coupled to each other.

In FIG. 5A, each of a gate of NMOS transistor N2, the gate of NMOS transistor N1, node Nd3, the first end of resistor R1 and the cathode of diode D5a are coupled to each other.

In some embodiments, current ICM1 flows through PMOS transistor P3 and NMOS transistor N2.

In some embodiments, current I5 flows through PMOS transistor P2, the set of diodes 502 and resistors R1.

In some embodiments, PMOS transistor P2, the set of diodes 502, resistor R1, diode D4a and NMOS transistor N1 are part of a circuit 501. In some embodiments, circuit 501 is integrated circuit 400A of FIG. 4A, and similar detailed description is therefore omitted.

In some embodiments, integrated circuit 500A is configured to operate in an ESD mode and a Normal mode.

In some embodiments, in a Normal mode of integrated circuit 500A, no ESD event (e.g., Normal mode) occurs at IO pad 108. In some embodiments, PMOS transistor P2 and PMOS transistor P3 are configured as a current mirror, and therefore current ICM1 is configured to mirror current I5 and vice versa. In some embodiments, a first path 550 (e.g., current ICM1) is a primary branch of the current mirror, and a second path 552 (e.g., current I5) is a tracking branch. In some embodiments, the second path 552 is configured to track the first path 550a of the current mirror.

In some embodiments, when no ESD event (e.g., Normal mode) occurs at IO pad 108, the current mirror (e.g., PMOS transistors P2 and P3) of integrated circuit 500A and the set of diodes 502, thereby causes integrated circuit 500A to have lower leakage current than other approaches.

In some embodiments, by utilizing at least the current mirror (e.g., PMOS transistors P2 and P3), NMOS transistor N2 or circuit 501 in integrated circuit 500A, causes integrated circuit 500A to have lower leakage current than other approaches.

In some embodiments, in an ESD mode of integrated circuit 500A, an ESD event occurs at IO pad 108 or node Nd2. In some embodiments, during an ESD event at IO pad 108 or node Nd1, circuit 501 is configured to operate in a manner similar to operation of integrated circuit 400A, and similar detailed description is therefore omitted.

In some embodiments, PMOS transistor P2, the set of diodes 502 and resistor R1 are referred to as an ESD detection circuit (not labelled), but the ESD detection circuit (not labelled) of FIG. 5A is configured to operate in a manner similar to the operation of ESD detection circuit 401 of FIG. 4A, and similar detailed description is therefore omitted.

Other types of circuits, configurations and arrangements of the diode D4a, the set of diodes 502, resistor R1, NMOS transistor N1, NMOS transistor N2, PMOS transistor P2 and PMOS transistor P3 are within the scope of the present disclosure.

In some embodiments, integrated circuit 500A is configured to achieve one or more benefits described herein.

Other configurations or quantities of circuits in integrated circuit 500A are within the scope of the present disclosure.

FIG. 5B is a circuit diagram of an integrated circuit 500B, in accordance with some embodiments.

Integrated circuit 500B is an embodiment of ESD clamp 130, and similar detailed description is therefore omitted.

Integrated circuit 500B is a variation of integrated circuit 400B of FIG. 4B, and similar detailed description is therefore omitted. In comparison with integrated circuit 400B, integrated circuit 500B further includes an NMOS transistor N4 and a PMOS transistor P4, and similar detailed description is therefore omitted.

In comparison with integrated circuit 400B, an NMOS transistor N3 replaces diode D5b of FIG. 4B, and similar detailed description is therefore omitted. In some embodiments, NMOS transistor N3 is a diode-coupled transistor 514, and operation of NMOS transistor N3 is similar to the diode D5b of FIG. 4B, and similar detailed description is therefore omitted.

Integrated circuit 500B includes a set of diodes 512, the resistor R2, PMOS transistor P1, PMOS transistor P4, NMOS transistor N3, NMOS transistor N4 and the diode D4b.

The set of diodes 512 is a variation of the set of diodes 412 of FIG. 4B, and similar detailed description is therefore omitted. In comparison with the set of diodes 412, the set of diodes 512 does not include diode D5b, and similar detailed description is therefore omitted.

In some embodiments, one or more diodes of the set of diodes 512 or diode D4b is a corresponding diode coupled transistor, as shown in FIG. 6.

Other numbers of diodes or threshold voltages of the set of diodes 512 or diode D4b are within the scope of the present disclosure.

NMOS transistor N3 is coupled between IO pad 108 and the cathode of diode D3b. NMOS transistor N3 is a diode-coupled transistor 514.

Each of a gate of NMOS transistor N3, a drain of NMOS transistor N3, a gate of NMOS transistor N4, and the cathode of diode D3b are coupled to each other.

In FIG. 5B, each of a source of NMOS transistor N3, a source of NMOS transistor N4, the cathode of diode D4b and the IO pad 108 are coupled to each other.

NMOS transistor N4 is coupled between IO pad 108 and a drain of PMOS transistor P4.

Each of a drain of NMOS transistor N4 and the drain of PMOS transistor P4 are coupled to each other.

PMOS transistor P4 is coupled between NMOS transistor N4 and the voltage supply rail 109 (or node Nd1).

Each of a source of PMOS transistor P4, the source of PMOS transistor P1, the second end of resistor R2 and the voltage supply rail 109 (or node Nd1) are coupled to each other.

In FIG. 5B, each of a gate of PMOS transistor P4, the gate of PMOS transistor P1, node Nd4, the first end of resistor R2 and the anode of diode D1b are coupled to each other.

In some embodiments, current ICM2 flows through NMOS transistor N4 and PMOS transistor P4.

In some embodiments, current I6 flows through NMOS transistor N3, the set of diodes 512 and resistor R2.

In some embodiments, NMOS transistor N3, the set of diodes 512, resistor R2, diode D4b and PMOS transistor P1 are part of a circuit 511. In some embodiments, circuit 511 is integrated circuit 400B of FIG. 4B, and similar detailed description is therefore omitted.

In some embodiments, integrated circuit 500B is configured to operate in an ESD mode and a Normal mode.

In some embodiments, in a Normal mode of integrated circuit 500B, no ESD event (e.g., Normal mode) occurs at IO pad 108. In some embodiments, NMOS transistor N3 and NMOS transistor N4 are configured as a current mirror, and therefore current ICM2 is configured to mirror current I6 and vice versa. In some embodiments, a first path 560 (e.g., current ICM2) is a primary branch of the current mirror, and a second path 562 (e.g., current I6) is a tracking branch. In some embodiments, the second path 562 is configured to track the first path 560 of the current mirror.

In some embodiments, when no ESD event (e.g., Normal mode) occurs at IO pad 108, the current mirror (e.g., NMOS transistors N3 and N4) of integrated circuit 500B and the set of diodes 512, thereby causes integrated circuit 500B to have lower leakage current than other approaches.

In some embodiments, by utilizing at least the current mirror (e.g., NMOS transistors N3 and N4), PMOS transistor P4 or circuit 511 in integrated circuit 500B, causes integrated circuit 500B to have lower leakage current than other approaches.

In some embodiments, in an ESD mode of integrated circuit 500B, an ESD event occurs at IO pad 108 or node Nd1. In some embodiments, during an ESD event at IO pad 108 or node Nd1, circuit 511 is configured to operate in a manner similar to operation of integrated circuit 400B, and similar detailed description is therefore omitted.

In some embodiments, NMOS transistor N3, the set of diodes 512 and resistor R2 are referred to as an ESD detection circuit (not labelled), but the ESD detection circuit (not labelled) of FIG. 5B is configured to operate in a manner similar to the operation of ESD detection circuit 401 of FIG. 4B, and similar detailed description is therefore omitted.

Other types of circuits, configurations and arrangements of the diode D4b, the set of diodes 512, resistor R2, PMOS transistor P1, PMOS transistor P4, NMOS transistor N3 and NMOS transistor N4 are within the scope of the present disclosure.

In some embodiments, integrated circuit 500B is configured to achieve one or more benefits described herein.

Other configurations or quantities of circuits in integrated circuit 500B are within the scope of the present disclosure.

FIG. 6 is a diagram of a circuit 600, in accordance with some embodiments.

In some embodiments, circuit 600 is usable in FIGS. 2A-2B, 3A-3B, 4A-4B and 5A-5B, in accordance with some embodiments.

In some embodiments, circuit 600 is usable as at least one of diode D1a, D2a, D3a, D4a, D5a, D1b, D2b, D3b, D4b or D5b of FIGS. 2A-2B, 3A-3B, 4A-4B and 5A-5B, and similar detailed description is therefore omitted.

Circuit 600 includes a transistor 602. In some embodiments, transistor 602 is an N-type transistor. In some embodiments, transistor 602 is an NFET. In some embodiments, transistor 602 is an NMOS transistor. Other transistor types or numbers of transistors in transistor 602 are within the scope of the present disclosure. In some embodiments, transistor 602 is a P-type transistor. In some embodiments, transistor 602 is a PFET. In some embodiments, transistor 602 is a PMOS transistor.

Transistor 602 is a diode-coupled transistor.

Each of a gate terminal G1 and a drain terminal D1 of transistor 602 are coupled to each other.

In some embodiments, the gate terminal G1 and the drain terminal D1 of transistor 602 correspond to at least one of an anode of diode D1a, anode of D2a, anode of D3a, anode of D4a, anode of D5a, anode of D1b, anode of D2b, anode of D3b, anode of D4b or anode of D5b, and a source terminal S1 of transistor 602 corresponds to at least one of a cathode of diode D1a, cathode of D2a, cathode of D3a, cathode of D4a, cathode of D5a, cathode of D1b, cathode of D2b, cathode of D3b, cathode of D4b or cathode of D5b, and similar detailed description is therefore omitted.

Other configurations of circuit 600 are within the scope of the present disclosure.

Other configurations or quantities of circuits in integrated circuit 600 are within the scope of the present disclosure.

FIGS. 7A-7G are block diagrams of corresponding resistive networks 700A, 700B, 700C, 700D, 700E, 700F and 700G, in accordance with some embodiments.

Resistive networks 700A, 700B, 700C, 700D, 700E, 700F and 700G are embodiments of at least one of resistor R1 or resistor R2, and similar detailed description is therefore omitted.

In some embodiments, resistive networks 700A, 700B, 700C, 700D, 700E, 700F and 700G are usable as at least one of resistor R1 or resistor R2, and similar detailed description is therefore omitted.

Resistive network 700A includes cell regions 718B(0)-718B(m−1).

Cell regions 718B(0)-718B(m−1) are coupled together (variously in series and/or in parallel (FIGS. 7B-7D, or the like) in a manner that represents a resistor, e.g., at least one of resistor R1 or resistor R2, having first and second terminals. In some embodiments, each of cell regions 718B(0)-718B(m−1) includes first and second resistive-sub-networks.

In FIG. 7A, resistive network 700A includes resistive-network cell regions 718B(0), 718B(1), . . . , 718B(m−2) and 718B(m−1) which abut each other relative to a first direction X, e.g., parallel to X-axis, and where m is a positive integer equal to or greater than 1.

Relative to the X-axis, FIG. 7A shows pairs of adjacent cell regions, e.g., 718B(1) and 718B(2), abutting horizontally with substantially no space between. In some embodiments (not shown), depending upon design considerations, e.g., routing, or the like, not every pair of adjacent cell regions is horizontally abutting, i.e., a significant space exists between one or more corresponding pairs of adjacent cell regions 718B(0)-718B(m−1).

Regarding FIGS. 7B-7D and 7F-7G, in each cell region, each first and second resistive-sub-networks is represented with a corresponding resistor symbol. For example, in FIG. 7B, cell region 718(1) is shown with a resistor symbol 780(1) and 782(1), and cell region 718(m−1) is shown with a resistor symbol 780(m−1) and 782(m−1).

In FIG. 7A, first and second resistive-sub-networks are coupled together (variously in series and/or in parallel (FIGS. 7B-7D, or the like) in a manner that represents at least one of resistor R1 or resistor R2 having first and second terminals.

In FIG. 7B, in some embodiments, one or more of cell regions 718B(0)-718B(m−1) is entirely series-coupled internally (ESCI), i.e., the first resistive-sub-network 784(1) is series-coupled together. For example, each of the resistors 780(0), . . . , 780(m−1) in the first resistive-sub-network 784(1) are series-coupled together with each other, in accordance with some embodiments.

In FIG. 7B, in some embodiments, one or more of cell regions 718B(0)-718B(m−1) is entirely series-coupled internally (ESCI), i.e., the second resistive-sub-network 784(2) is series-coupled together. For example, each of the resistors 782(0), . . . , 782(m−1) in the second resistive-sub-network 784(2) are series-coupled together with each other, in accordance with some embodiments.

In FIG. 7C, in some embodiments, the first resistive-sub-network 784(1) is series-coupled together with the second resistive-sub-network 784(2). For example, each of the resistors 780(0), . . . , 780(m−1) in the first resistive-sub-network 784(1) are series-coupled together with each of the resistors 782(0), . . . , 782(m−1) in the second resistive-sub-network 784(2) by M1 conductor 772(13) and vias 770, in accordance with some embodiments.

In some embodiments, the first resistive-sub-network 784(1) and the second resistive-sub-network 784(2) are part of current path 784(3). In some embodiments, current path 784(3) is described as having a serpentine shape.

Regarding FIG. 7D, resistive network 700C shows cell regions 718D(0)-718D(1) but does not show cell regions 718D(2)-718D(m−1), the latter not being shown for simplicity of illustration. In some embodiments, each of cell regions 718D(0)-718D(m−1) has an ESCI configuration.

In cell region 718D(0), resistor 780(0) is coupled in series to resistor 782(0) as indicated by current path 784(4). In cell region 718D(1), resistor 780(1) is coupled in series to resistor 782(1) as indicated by current path 784(5). Current paths 784(4) and 784(5) are coupled to each other, as indicated by current path 784(6). In some embodiments, each of current paths 784(4) and 784(5) is described as having a serpentine shape.

In FIG. 7D, relative to a long axis of symmetry parallel to a second direction Y, e.g., a direction parallel to the Y-axis, cell region 718D(0) has a first orientation. More generally, even-numbered ones of cell regions 718D(0)-718D(m−1) have the first orientation, i.e., cell regions 718D(j) have the first orientation, where j is an integer, j is in a range (0)≤j≤(m−1), and j=2k, where k is a non-negative integer.

Also in FIG. 7D, relative to a long axis of symmetry parallel to the Y-axis, cell region 718D(1) has a second orientation. Relative to the Y-axis, the second orientation is mirror symmetric with respect to the first axis. More generally, odd-numbered ones of cell regions 718D(0)-718D(m−1) have the second orientation, i.e., cell regions 718D(q) have the second orientation, where q is an integer, q is in a range (0)≤q≤(m−1), and q=(2k+1), where k is a non-negative integer.

In FIG. 7E, resistive network 700E includes resistive-network cell regions 718B(0)-718B(m−1) which abut each other relative to the Y-axis.

Relative to the Y-axis, FIG. 7E shows pairs of adjacent cell regions, e.g., 718B(1) and 718B(2), abutting vertically with substantially no space between. In some embodiments (not shown), depending upon design considerations, e.g., routing, or the like, not every pair of adjacent cell regions is vertically abutting, i.e. a significant space exists between one or more corresponding pairs of adjacent cell regions 718B(0)-718B(m−1).

Regarding FIG. 7F, resistive network 700F shows cell regions 718F(0)-718F(1) but does not show cell regions 718F(2)-718F(m−1), the latter not being shown for simplicity of illustration.

In FIG. 7F, in some embodiments, resistor 780(0) is series-coupled together with resistor 782(0) by M1 conductor 772(14) and vias 770 and is part of current path 784(7), resistor 782(0) is series-coupled together with resistor 780(1) by M1 conductor 772(15) and vias 770 and is part of current path 784(8), resistor 780(1) is series-coupled together with resistor 782(1) by M1 conductor 772(16) and vias 770 and is part of current path 784(9), and so forth.

Regarding FIG. 7G, resistive network 700G shows cell regions 718G(0)-718G(1) but does not show cell regions 718G(2)-718G(m−1), the latter not being shown for simplicity of illustration. In some embodiments, each of cell regions 718G(0)-718G(m−1) has an ESCI configuration.

In cell region 718G(0), resistor 780(0) is coupled in series to resistor 782(0) as indicated by current path 784(10). In cell region 718G(1), resistor 780(1) is coupled in series to resistor 782(1) as indicated by current path 784(12). In some embodiments, each of current paths 784(10) and 784(12) is described as having a serpentine shape.

In FIG. 7F, in some embodiments, resistor 782(0) is series-coupled together with resistor 780(1) by M1 conductor 772(17) and vias 770 and is part of current path 784(11).

In some embodiments, at least one of resistive network 700A, 700B, 700C, 700D, 700E, 700F or 700G is configured to achieve one or more benefits described herein.

Other configurations or quantities of circuits in at least one of resistive network 700A, 700B, 700C, 700D, 700E, 700F or 700G are within the scope of the present disclosure.

FIGS. 8A and 8B are diagrams of an integrated circuit 800, in accordance with some embodiments. FIGS. 8C-8D are corresponding cross-sectional views of integrated circuit 800, in accordance with some embodiments.

FIG. 8A is a top view of a portion 800A of integrated circuit 800, simplified for ease of illustration.

FIG. 8B is a top view of a portion 800B of integrated circuit 800, simplified for ease of illustration.

FIG. 8C is a cross-sectional view of integrated circuit 800 as intersected by plane A-A′, in accordance with some embodiments.

FIG. 8D is a cross-sectional view of integrated circuit 800 as intersected by plane B-B′, in accordance with some embodiments.

Portion 800A includes one or more features of an oxide diffusion (OD) level or an active level, a metal over diffusion (MD) level, a gate (POLY) level, a via over gate (VG) level, a via over diffusion (VD) level and a metal 0 (M0) level.

Portion 800B includes one or more features of the MD level, the POLY level, the VG level, the VD level and the M0 level.

For ease of illustration, some of the labeled elements of one or more of FIGS. 8A-8D are not labelled in one or more of FIGS. 8A-8D. In some embodiments, integrated circuit 800 includes additional elements not shown in FIGS. 8A-8D.

Integrated circuit 800 is an embodiment of at least one of resistive network 700A, 700B, 700C, 700D, 700E, 700F and 700G of corresponding FIGS. 7A, 7B, 7C, 7D, 7E, 7F and 7G, and similar detailed description is therefore omitted.

In some embodiments, integrated circuit 800 is usable as at least one of resistor R1 or resistor R2, and similar detailed description is therefore omitted.

Integrated circuit 800 is manufactured by a corresponding layout design similar to integrated circuit 800. For brevity FIGS. 8A-8D are described as integrated circuit 800. In some embodiments, each of FIGS. 8A-8D is also a corresponding layout design, and each structural element of integrated circuit 800 is a corresponding layout pattern, and structural relationships including alignment, lengths and widths, as well as configurations and layers of a corresponding layout design of integrated circuit 800 are similar to the structural relationships and configurations and layers of integrated circuit 800, and similar detailed description will not be described for brevity.

Integrated circuit 800 includes a cell 801. The cell 801 has cell boundaries 801a and 801b that extend in a first direction X, and cell boundaries 801c and 801d that extend in a second direction Y. In some embodiments, the second direction Y is different from the first direction X. In some embodiments, integrated circuit 800 abuts other cells (not shown) along cell boundaries 801c and 801d. In some embodiments, integrated circuit 800 abuts other cells (not shown) along cell boundaries 801a and 801b that extend in the first direction X. In some embodiments, integrated circuit 800 is a single height standard cell.

In some embodiments, cell 801 is a standard cell defined by cell boundaries 801a, 801b, 801c and 801d. In some embodiments, cell 801 is bounded by cell boundaries 801a, 801b, 801c and 801d, and thus corresponds to a region of circuit components or devices that are part of a standard cell.

In some embodiments, e.g., the embodiments depicted in FIGS. 8A-8D discussed below, a given cell has cell boundaries 801c and 801d that are overlapped by corresponding gates 804a and 804f. For example, in some embodiments, cell boundaries 801c and 801d of cell 801 are identified by gates 804a and 804f.

Integrated circuit 800 includes a substrate 890 (FIGS. 8C-8D). In some embodiments, substrate 890 is a p-type substrate. In some embodiments, substrate 890 is a p-type well in an underlaying substrate (not shown). In some embodiments, substrate 890 includes an elemental semiconductor including silicon or germanium in crystal, polycrystalline, or an amorphous structure; a compound semiconductor including silicon carbide, gallium arsenic, gallium phosphide, indium phosphide, indium arsenide, and indium antimonide; an alloy semiconductor including SiGe, GaAsP, AlInAs, AlGaAs, GaInAs, GaInP, and GaInAsP; any other suitable material; or combinations thereof. In some embodiments, the alloy semiconductor substrate has a gradient SiGe feature in which the Si and Ge composition change from one ratio at one location to another ratio at another location of the gradient SiGe feature. In some embodiments, the alloy SiGe is formed over a silicon substrate. In some embodiments, substrate 890 is a strained SiGe substrate. In some embodiments, the semiconductor substrate has a semiconductor on insulator structure, such as a silicon on insulator (SOI) structure. In some embodiments, the semiconductor substrate includes a doped epi layer or a buried layer. In some embodiments, the compound semiconductor substrate has a multilayer structure, or the substrate includes a multilayer compound semiconductor structure.

In some embodiments, integrated circuit 800 is incorporated on a single integrated circuit (IC), or on a single semiconductor substrate. In some embodiments, integrated circuit 800 includes one or more ICs incorporated on one or more single semiconductor substrates.

Integrated circuit 800 further includes one or more active regions 802a or 802b (collectively referred to as a “set of active regions 802”) extending in a first direction X.

The set of active regions is embedded in a substrate 890. Substrate 890 has a front-side (not labelled) and a back-side (not labelled) opposite from the front-side.

Active regions 802a or 802b of the set of active regions 802 are separated from one another in a second direction Y. In some embodiments, the second direction Y is different from the first direction X. The set of active regions 802 is manufactured by a corresponding set of active region layout patterns of a layout design similar to integrated circuit 800.

In some embodiments, the set of active regions 802 are located on a front-side (not labelled) of at least integrated circuit 800. In some embodiments, active regions 802a or 802b of the set of active regions 802 are manufactured by corresponding active region layout patterns of the set of active region layout patterns.

In some embodiments, the set of active regions 802 is referred to as an oxide diffusion (OD) region which defines the source or drain diffusion regions of at least integrated circuit 800.

In some embodiments, active region 802a of the set of active regions 802 is a source region and/or a drain region of one or more NMOS transistors, and active region 802a of the set of active regions 802 is a source region and/or a drain region of one or more PMOS transistors. In some embodiments, active region 802a of the set of active regions 802 is a source region and/or a drain region of one or more PMOS transistors, and active region 802a of the set of active regions 802 is a source region and/or a drain region of one or more NMOS transistors.

In some embodiments, one of active region 802a or 802b is an N-type doped S/D region embedded in a dielectric material of substrate 890, and another of active region 802a or 802b is a P-type doped S/D region embedded in a dielectric material of substrate 890.

In some embodiments, the set of active regions 802 is located on a first level. In some embodiments, the first level corresponds to an active level or an OD level of integrated circuit 800.

Other numbers of active regions in the set of active regions 802 are within the scope of the present disclosure.

Other configurations, arrangements on other levels or quantities of regions in the set of active regions 802 are within the scope of the present disclosure.

Integrated circuit 800 further includes an insulating region 803.

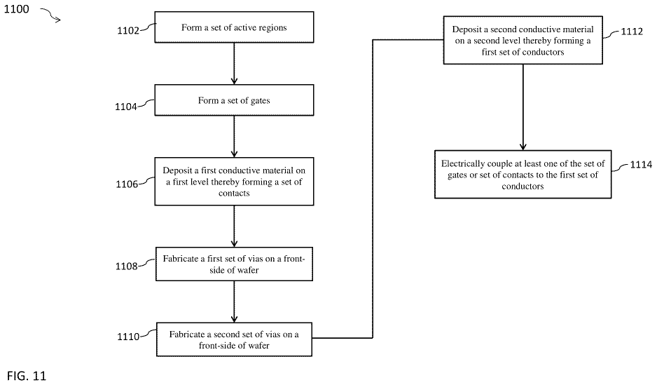

Insulating region 803 is configured to electrically isolate one or more elements of the set of active regions 802, the set of gates 804 or the set of contacts 806 from one another, or from other elements (not shown). In some embodiments, insulating region 803 includes multiple insulating regions deposited at different times from each other during method 8100 (FIG. 11). In some embodiments, insulating region 803 is a dielectric material. In some embodiments, the dielectric material includes silicon dioxide, silicon oxy-nitride, or the like.

Other configurations, arrangements on other layout levels or other numbers of portions in insulating region 803 are within the scope of the present disclosure.

Integrated circuit 800 further includes one or more of gates 804a, 804b, 804c, 804d, 804 e or 804 f (collectively referred to as a “set of gates 804”) extending in the second direction Y. Each of the gates of the set of gates 804 is separated from an adjacent gate of the set of gates 804 in the first direction X by a pitch CPP. In some embodiments, adjacent elements are elements that are directly next to each other. For example, if a first element is adjacent to a second element, then the second element and the first element are directly next to each other.

In some embodiments, the set of gates 804 is manufactured by a corresponding set of gate layout patterns. In some embodiments, gates 804a, 804b, 804c, 804d, 804e or 804f of the set of gates 804 are manufactured by a corresponding gate layout pattern of the set of gate layout patterns.

In some embodiments, one or more of gates 804b, 804c, 804d or 804e of the set of gates 804 is the gate of a corresponding transistor.

In some embodiments, one or more of gates 804a or 804f of the set of gates 804 is a dummy gate. In some embodiments, a dummy gate is a non-functional gate. In some embodiments, dummy gates are also referred to as continuous poly over diffusion edge (CPODE) gates. In some embodiments, at least one of gate 804a or 804f overlaps corresponding cell boundaries 801c or 801d. Other gates configured as dummy gates are within the scope of the present disclosure.

The set of gates 804 is above the set of active regions 802. The set of gates 804 is positioned on a second level different from the first level. In some embodiments, the second level is different from the first level. In some embodiments, the second level corresponds to the POLY level of integrated circuit 800.

In some embodiments, the POLY level is above the OD level.

Other configurations, arrangements on other levels or quantities of gates in the set of gates 804 are within the scope of the present disclosure.

Integrated circuit 800 further includes one or more of contacts 806a, 806b, 806c, 806d or 806 e (collectively referred to as a “set of contacts 806”) extending in the second direction Y.

Each of the contacts of the set of contacts 806 is separated from an adjacent contact of the set of contacts 806 in at least the first direction X. In some embodiments, adjacent elements are elements that are directly next to each other. For example, if a first element is adjacent to a second element, then the second element and the first element are directly next to each other.

The set of contacts 806 is manufactured by a corresponding set of contact layout patterns. In some embodiments, contact 806a, 806b, 806c, 806d or 806e of the set of contacts 806 is manufactured by a corresponding contact layout pattern of the set of contact layout patterns.

In some embodiments, the set of contacts 806 is also referred to as a set of metal over diffusion (MD) structures.

In some embodiments, at least one of contact 806a, 806b, 806c, 806d or 806e of the set of contacts 806 is a source terminal or a drain terminal of a corresponding NMOS transistor or a corresponding PMOS transistor.

In some embodiments, the set of contacts 806 overlap the set of active regions 802. The set of contacts 806 is located on a third level. In some embodiments, the third level corresponds to the contact level or an MD level of one or more of integrated circuit 800. In some embodiments, the third level is the same as the second level. In some embodiments, the third level is different from the first level.

Other configurations, arrangements on other levels or quantities of contacts in the set of contacts 806 are within the scope of the present disclosure.

Integrated circuit 800 further includes one or more conductors 820a, 820b, . . . , 820j or 820k (collectively referred to as a “set of conductors 820”) extending in at least the first direction X.

Each of conductors 820a, 820b, . . . , 820j or 820k of the set of conductors 820 are separated from each other in at least the second direction Y.

In some embodiments, while each of conductors 820a, 820b, . . . , 820j or 820k is shown as continuous patterns, one or more of conductors 820a, 820b, . . . , 820j or 820k is separated to form discontinuous patterns. In some embodiments, conductors 820a, 820b and 820c are one continuous pattern. In some embodiments, conductors 820d, 820e and 820f are one continuous pattern. In some embodiments, conductors 820g, 820h and 820i are one continuous pattern. In some embodiments, conductors 820j and 820k are one continuous pattern.

The set of conductors 820 is manufactured by a corresponding set of conductive feature layout patterns. In some embodiments, conductor 820a, 820b, . . . , 820j or 820k of the set of conductors 820 is manufactured by a corresponding conductive feature layout pattern of the set of conductive feature layout patterns.

In some embodiments, the set of conductors 820 are located on the front-side (not labelled) of integrated circuit 800.

The set of conductors 820 overlap the set of gates 804, the set of active regions 802 and the set of contacts 806. In some embodiments, the set of conductors 820 is on a fourth level. In some embodiments, the fourth level is different from the first level, the second level and the third level. In some embodiments, the fourth level corresponds to the M0 level of integrated circuit 800. In some embodiments, the M0 level is above the OD level, the POLY level, the MD level, the VG level and the VD level. In some embodiments, the set of conductors 820 are located on other metal layers (e.g., metal-1 (M1), metal-2 (M2), etc.).

Each conductor in the set of conductors 820 is separated from an adjacent conductor in the set of conductors 820 in the second direction Y by a pitch (not labelled).

In some embodiments, the set of conductors 820 corresponds to 5 M0 routing tracks in integrated circuit 800.

In some embodiments, the set of conductors 820 corresponds to 5 M0 routing tracks (e.g., set of gridlines 830) in integrated circuit 800.

In some embodiments, the set of gridlines 830 extend in the first direction and designate a corresponding M0 routing track in integrated circuit 800. In some embodiments, the set of gridlines 830 includes gridlines 830a, 830b, . . . , 830e.

In some embodiments, gridline 830a is overlapped by conductors 820a, 820b and 820c.

In some embodiments, gridline 830b is overlapped by conductors 820d, 820e and 820f.

In some embodiments, gridline 830d is overlapped by conductors 820g, 820h and 820i.

In some embodiments, gridline 830e is overlapped by conductors 820j and 820k.

Other numbers of M0 routing tracks are within the scope of the present disclosure.

Other configurations, arrangements on other layout levels or quantities of conductors in the set of conductors 820 are within the scope of the present disclosure.

Integrated circuit 800 further includes one or more vias 810a, 810b, . . . , 810i or 810j (collectively referred to as a “set of vias 810”).

The set of vias 810 is manufactured by a corresponding set of via patterns of integrated circuit 800. In some embodiments, vias 810a, 810b, . . . , 810i or 810j of the set of vias 810 are manufactured by corresponding via patterns of the set of via patterns of integrated circuit 800.

The set of vias 810 is positioned at a via over diffusion (VD) level of integrated circuit 800. In some embodiments, the VD level is above the MD and the OD level. In some embodiments, the VD level is between the MD level and the M0 level. In some embodiments, the VD level is between the third level and the fourth level. Other levels are within the scope of the present disclosure.

In some embodiments, the set of vias 810 is located where the set of contacts 806 is overlapped by the set of conductors 820. In some embodiments, the set of vias 810 is between the set of contacts 806 and the set of conductors 820.

In some embodiments, each of conductors 820d, 820g, 820e, 820h, 820f and 820i are electrically coupled to each other in a serial manner, thereby forming the first or second resistive-sub-network of FIGS. 7A-7G. For example, each of conductors 820d, 820g, 820e, 820h, 820f and 820i are electrically coupled to each other in a serial manner and correspond to resistor symbol 780(1) or 782(1) of FIG. 7B, and similar detailed description is therefore omitted.

In some embodiments, each of conductors 820d, 820g, 820e, 820h, 820f and 820i are electrically coupled to each other in a serial manner. For example, in some embodiments, conductor 820d is electrically coupled to contact 806a by via 810a, contact 806a is further electrically coupled to conductor 820g by via 810f, conductor 820g is electrically coupled to contact 806b by via 810g, contact 806b is further electrically coupled to conductor 820e by via 810b, conductor 820e is electrically coupled to contact 806c by via 810c, contact 806c is further electrically coupled to conductor 820h by via 810h, conductor 820h is electrically coupled to contact 806d by via 810i, contact 806d is further electrically coupled to conductor 820f by via 810d, conductor 820f is electrically coupled to contact 806e by via 810e, contact 806e is further electrically coupled to conductor 820i by via 810j.

Other configurations, arrangements on other layout levels or quantities of patterns in at least the set of vias 810 are within the scope of the present disclosure.

Integrated circuit 800 further includes one or more vias 812a, 812b, . . . , 812g or 812h (collectively referred to as a “set of vias 812”).

The set of vias 812 is manufactured by a corresponding set of via patterns of integrated circuit 800. In some embodiments, vias 812a, 812b, . . . , 812g or 812h of the set of vias 812 are manufactured by corresponding via patterns of the set of via patterns of integrated circuit 800.

The set of vias 812 is positioned at a via over gate (VG) level of integrated circuit 800. In some embodiments, the VG level is between the POLY level and the M0 level. In some embodiments, the VG level is between the second level and the fourth level. Other levels are within the scope of the present disclosure.

In some embodiments, the set of vias 812 is located where the set of gates 804 is overlapped by the set of conductors 820. In some embodiments, the set of vias 812 is between the set of gates 804 and the set of conductors 820.

In some embodiments, each of conductors 820a, 820j, 820b, 820k and 820c are electrically coupled to each other in a serial manner, thereby forming the first or second resistive-sub-network of FIGS. 7A-7G. For example, each of conductors 820a, 820j, 820b, 820k and 820c are electrically coupled to each other in a serial manner and correspond to resistor symbol 780(1) or 782(1) of FIG. 7B, and similar detailed description is therefore omitted.

In some embodiments, each of conductors 820a, 820j, 820b, 820k and 820c are electrically coupled to each other in a serial manner. For example, in some embodiments, conductor 820a is electrically coupled to gate 804b by via 812a, gate 804b is further electrically coupled to conductor 820j by via 812e, conductor 820j is electrically coupled to gate 804c by via 812f, gate 804c is further electrically coupled to conductor 820b by via 812b, conductor 820b is electrically coupled to gate 804d by via 812c, gate 804d is further electrically coupled to conductor 820k by via 812g, conductor 820k is electrically coupled to gate 804e by via 812h, gate 804e is further electrically coupled to conductor 820c by via 812d.

Other configurations, arrangements on other layout levels or quantities of patterns in at least set of vias 812 are within the scope of the present disclosure.

In some embodiments, at least one gate of the set of gates 804 are formed using a doped or non-doped polycrystalline silicon (or polysilicon). In some embodiments, at least one gate of the set of gates 804 include a metal, such as Al, Cu, W, Ti, Ta, TiN, TaN, NiSi, CoSi, other suitable conductive materials, or combinations thereof.

In some embodiments, at least one conductor of the set of contacts 806, at least one conductor of a set of conductors 820, at least one via of the set of vias 810 or at least one via of the set of vias 812 includes one or more layers of a conductive material, a metal, a metal compound or a doped semiconductor. In some embodiments, the conductive material includes Tungsten, Cobalt, Ruthenium, Copper, or the like or combinations thereof. In some embodiments, a metal includes at least Cu (Copper), Co, W, Ru, Al, or the like. In some embodiments, a metal compound includes at least AlCu, W-TiN, TiSix, NiSix, TiN, TaN, or the like. In some embodiments, a doped semiconductor includes at least doped silicon, or the like.

In some embodiments, integrated circuit 800 is configured to achieve one or more benefits described herein.

Other materials, configurations, arrangements on other levels or quantities of elements in integrated circuit 800 are within the scope of the present disclosure.

FIG. 9 is a diagram of a circuit 900, in accordance with some embodiments.

In some embodiments, circuit 900 is usable as header circuit 110 of FIGS. 1A-1B, and similar detailed description is therefore omitted.

Circuit 900 includes a transistor 902. In some embodiments, transistor 902 is a P-type transistor. In some embodiments, transistor 902 is a PFET. In some embodiments, transistor 902 is a PMOS transistor.

Other transistor types or numbers of transistors in transistor 902 are within the scope of the present disclosure. In some embodiments, transistor 902 is an N-type transistor. In some embodiments, transistor 902 is an NFET. In some embodiments, transistor 902 is an NMOS transistor.

Transistor 902 is coupled between voltage supply node 104 and voltage supply rail 109.

Transistor 902 is coupled to the voltage supply node 104 of the voltage supply TVDD and a voltage supply rail 109. Transistor 902 is configured to receive the first voltage from the first voltage supply TVDD.

Transistor 902 is further configured to receive a control signal GC. In some embodiments, control signal GC is sent by a source (not shown). In some embodiments, transistor 902 is configured to be turned on or off in response to the control signal GC. In some embodiments, when transistor 902 is configured to be turned on, and then transistor 902 is configured to provide the voltage to the voltage supply rail 109 (referred to as a virtual voltage supply (VDD) or the second voltage supply VDD).

In some embodiments, the gate terminal G2 is configured to receive the control signal GC. In some embodiments, the drain terminal D2 is coupled to the voltage supply rail 109. In some embodiments, the source terminal S2 is coupled to the voltage supply node 104 of the voltage supply TVDD.

Other configurations or quantities of transistor 902 are within the scope of the present disclosure.

Other configurations or quantities of circuits in integrated circuit 900 are within the scope of the present disclosure.

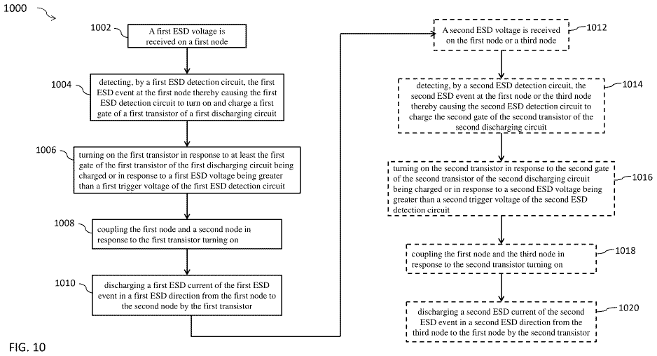

FIG. 10 is a flowchart of a method 1000 of operating an ESD circuit, in accordance with some embodiments. In some embodiments, the circuit of method 1000 includes at least integrated circuit 100A-100B, 200A-200B, 300A-300B, 400A-400C and 500A-500C (FIGS. 1A-1B, 2A-2B, 3A-3B, 4A-4C and 5A-5C). It is understood that additional operations may be performed before, during, and/or after the method 1000 depicted in FIG. 10, and that some other processes may only be briefly described herein. It is understood that method 1000 utilizes features of one or more of integrated circuit 100A-100B, 200A-200B, 300A-300B, 400A-400B, 500A-500B, 700A-700G or 800 or circuit 600 or 900.

At operation 1002 of method 1000, a first ESD voltage is received on a first node. In some embodiments, the first node of method 1000 includes IO pad 108. In some embodiments, the first ESD voltage is greater than a reference supply voltage VSS of reference voltage supply node 106. In some embodiments, the first ESD voltage corresponds to a first ESD event (e.g., PS mode).

At operation 1004 of method 1000, a first ESD detection circuit detects the first ESD event at the first node thereby causing the first ESD detection circuit to turn on and charge a first gate of a first transistor of a first discharging circuit.

In some embodiments, detecting, by the first ESD detection circuit, the first ESD event at the first node comprises detecting, by the first ESD detection circuit, the first ESD event at the first node in response to the first ESD voltage being greater than a first trigger voltage of the first ESD detection circuit.

In some embodiments, the first ESD detection circuit of method 1000 includes at least ESD detection circuit 201 or 401. In some embodiments, the first ESD detection circuit of method 1000 includes at least the set of diodes 502, resistor R1 or PMOS transistor P2.

In some embodiments, the first discharging circuit of method 1000 includes at least NMOS transistor N1. In some embodiments, the first transistor of method 1000 includes at least NMOS transistor N1.

In some embodiments, the first transistor is coupled between the first node and a second node. In some embodiments, the second node is node 106 or VSS. In some embodiments, the first ESD detection circuit being coupled between at least the first node and the second node.

At operation 1006 of method 1000, the first transistor is turned on in response to the first gate of the first transistor of the first discharging circuit being charged or in response to a first ESD voltage being greater than a first trigger voltage of the first ESD detection circuit.

In some embodiments, the first trigger voltage is equal to a sum of each threshold voltage of each corresponding diode in a first set of diodes, the first set of diodes being part of the first ESD detection circuit.

In some embodiments, the first trigger voltage of method 1000 includes at least Vtrigger1 or Vtrigger3.

In some embodiments, the first set of diodes of method 1000 includes at least set of diodes 202 or 402. In some embodiments, the first set of diodes of method 1000 includes at least the set of diodes 502 and PMOS transistor P2.

At operation 1008 of method 1000, the first node is coupled to the second node in response to the first transistor turning on.

At operation 1010 of method 1000, a first ESD current of the first ESD event at the first node is discharged in a first ESD direction from the first node to the second node by the first transistor.

In some embodiments, the first ESD current corresponds to the reverse ESD direction. In some embodiments, the first ESD current includes the ESD current I1 or I2 in the reverse ESD direction from node IO pad 108 to node Nd2.

At operation 1012 of method 1000, a second ESD voltage is received on the second node.

In some embodiments, the second ESD voltage corresponds to a second ESD event (ND mode). In some embodiments, the second ESD event is a negative-to-VDD mode.

At operation 1014 of method 1000, a second ESD detection circuit detects the second ESD event at the first node or a third node thereby causing the second ESD detection circuit to turn on and charge a second gate of a second transistor of a second discharging circuit.

In some embodiments, detecting, by the second ESD detection circuit, the second ESD event at the first node comprises detecting, by the second ESD detection circuit, the second ESD event at the first node in response to the second ESD voltage being greater than a second trigger voltage of the second ESD detection circuit.

In some embodiments, the second ESD detection circuit of method 1000 includes at least ESD detection circuit 211 or 411. In some embodiments, the second ESD detection circuit of method 1000 includes at least the set of diodes 512, resistor R2 or NMOS transistor N3.

In some embodiments, the second discharging circuit of method 1000 includes at least PMOS transistor P1. In some embodiments, the second transistor of method 1000 includes at least PMOS transistor P1.

In some embodiments, the second transistor is coupled between the first node and a third node. In some embodiments, the third node is voltage supply rail 109 or VVDD. In some embodiments, the second ESD detection circuit being coupled between at least the first node and the third node.

At operation 1016 of method 1000, the first transistor is turned on in response to the gate of the first transistor of the discharging circuit being charged or in response to a second ESD voltage being greater than a second trigger voltage of the second ESD detection circuit.

In some embodiments, the second trigger voltage is equal to a sum of each threshold voltage of each corresponding diode in a second set of diodes, the second set of diodes being part of the second ESD detection circuit.

In some embodiments, the second trigger voltage of method 1000 includes at least Vtrigger2 or Vtrigger4.

In some embodiments, the second set of diodes of method 1000 includes at least set of diodes 212 or 412. In some embodiments, the second set of diodes of method 1000 includes at least the set of diodes 512 and NMOS transistor N3.

At operation 1018 of method 1000, the first node is coupled to the third node in response to the second transistor turning on.

At operation 1020 of method 1000, a second ESD current of the second ESD event is discharged in a second ESD direction from the third node to the first node by the second transistor.

In some embodiments, the second ESD current corresponds to the reverse ESD direction. In some embodiments, the second ESD current includes the ESD current I3 or I4 in the reverse ESD direction from the voltage supply rail 109 to IO pad 108.

In some embodiments, one or more of the operations of method 1000 is not performed.

For brevity, method 1000 is described with respect to at least portions of FIGS. 1A-1B, 2A-2B, 3A-3B, 4A-4B, 5A-5B, 6, 7A-7G, 8A-8D and 9, but method 1000 further includes the operation of each of FIGS. 1A-1B, 2A-2B, 3A-3B, 4A-4B, 5A-5B, 6, 7A-7G, 8A-8D and 9, in accordance with some embodiments.

In some embodiments, other order of operations of method 1000 is within the scope of the present disclosure. Method 1000 includes exemplary operations, but the operations are not necessarily performed in the order shown. Operations may be added, replaced, changed order, and/or eliminated as appropriate, in accordance with the spirit and scope of disclosed embodiments.

FIG. 11 is a functional flow chart of method 1100 of manufacturing an IC device, in accordance with some embodiments. It is understood that additional operations may be performed before, during, and/or after the method 1100 depicted in FIG. 11, and that some other processes may only be briefly described herein.

In some embodiments, other order of operations of method 1100-1300 is within the scope of the present disclosure. Method 1100-1300 includes exemplary operations, but the operations are not necessarily performed in the order shown. Operations may be added, replaced, changed order, and/or eliminated as appropriate, in accordance with the spirit and scope of disclosed embodiments. In some embodiments, one or more of the operations of at least method 1100, 1200 or 1300 is not performed.

In some embodiments, method 1100 is an embodiment of operation 1204 of method 1200. In some embodiments, the methods 1100-1300 are usable to manufacture or fabricate at least integrated circuit 100A-100B, 200A-200B, 300A-300B, 400A-400B, 500A-500B, 600, 700A-700G, 800 or 900. In some embodiments, method 1100 is useable to manufacture or fabricate at least integrated circuit 800. In some embodiments, while method 1100 is described to manufacture or fabricate at least integrated circuit 800, method 1100 is also useable to manufacture or fabricate at least integrated circuit 100A-100B, 200A-200B, 300A-300B, 400A-400B, 500A-500B, 600, 700A-700G or 900.

In operation 1102 of method 1100, a set of active regions is formed.

In some embodiments, the set of active regions of method 1100 includes the set of active regions 802.

In some embodiments, operation 1102 further includes fabricating source and drain regions of the set of transistors in a first well. In some embodiments, the first well comprises p-type dopants. In some embodiments, the p-dopants include boron, aluminum or other suitable p-type dopants. In some embodiments, the first well comprises an epi-layer grown over a substrate. In some embodiments, the epi-layer is doped by adding dopants during the epitaxial process. In some embodiments, the epi-layer is doped by ion implantation after the epi-layer is formed. In some embodiments, the first well is formed by doping the substrate. In some embodiments, the doping is performed by ion implantation. In some embodiments, the first well has a dopant concentration ranging from 1×10¹² atoms/cm³ to 1×10¹⁴ atoms/cm³.

In some embodiments, the first well comprises n-type dopants. In some embodiments, the n-type dopants include phosphorus, arsenic or other suitable n-type dopants. In some embodiments, the n-type dopant concentration ranges from about 1×10¹² atoms/cm³ to about 1×10¹⁴ atoms/cm³.

In some embodiments, the formation of the source/drain features includes, a portion of the substrate is removed to form recesses at an edge of spacers, and a filling process is then performed by filling the recesses in the substrate. In some embodiments, the recesses are etched, for example, a wet etching or a dry etching, after removal of a pad oxide layer or a sacrificial oxide layer. In some embodiments, the etch process is performed to remove a top surface portion of the active region adjacent to an isolation region, such as an STI region. In some embodiments, the filling process is performed by an epitaxy or epitaxial (epi) process. In some embodiments, the recesses are filled using a growth process which is concurrent with an etch process where a growth rate of the growth process is greater than an etch rate of the etch process. In some embodiments, the recesses are filled using a combination of growth process and etch process. For example, a layer of material is grown in the recess and then the grown material is subjected to an etch process to remove a portion of the material. Then a subsequent growth process is performed on the etched material until a desired thickness of the material in the recess is achieved. In some embodiments, the growth process continues until a top surface of the material is above the top surface of the substrate. In some embodiments, the growth process is continued until the top surface of the material is co-planar with the top surface of the substrate. In some embodiments, a portion of the first well is removed by an isotropic or an anisotropic etch process. The etch process selectively etches the first well without etching a gate structure and any spacers. In some embodiments, the etch process is performed using a reactive ion etch (RIE), wet etching, or other suitable techniques. In some embodiments, a semiconductor material is deposited in the recesses to form the source/drain features. In some embodiments, an epi process is performed to deposit the semiconductor material in the recesses. In some embodiments, the epi process includes a selective epitaxy growth (SEG) process, CVD process, molecular beam epitaxy (MBE), other suitable processes, and/or combination thereof. The epi process uses gaseous and/or liquid precursors, which interact with a composition of substrate. In some embodiments, the source/drain features include epitaxially grown silicon (epi Si), silicon carbide, or silicon germanium. Source/drain features of the IC device associated with the gate structure are in-situ doped or undoped during the epi process in some instances. When source/drain features are undoped during the epi process, source/drain features are doped during a subsequent process in some instances. The subsequent doping process is achieved by an ion implantation, plasma immersion ion implantation, gas and/or solid source diffusion, other suitable processes, and/or combination thereof. In some embodiments, source/drain features are further exposed to annealing processes after forming source/drain features and/or after the subsequent doping process.

In operation 1104 of method 1100, a set of gates is formed.

In some embodiments, the set of gates includes the set of gates 804.

In some embodiments, fabricating the gate regions of operation 1104 includes performing one or more deposition processes to form one or more dielectric material layers. In some embodiments, a deposition process includes a chemical vapor deposition (CVD), a plasma enhanced CVD (PECVD), an atomic layer deposition (ALD), or other process suitable for depositing one or more material layers. In some embodiments, fabricating the gate regions includes performing one or more deposition processes to form one or more conductive material layers. In some embodiments, fabricating the gate regions includes forming gate electrodes or dummy gate electrodes. In some embodiments, fabricating the gate regions includes depositing or growing at least one dielectric layer, e.g., gate dielectric. In some embodiments, gate regions are formed using a doped or non-doped polycrystalline silicon (or polysilicon). In some embodiments, the gate regions include a metal, such as Al, Cu, W, Ti, Ta, TiN, TaN, NiSi, CoSi, other suitable conductive materials, or combinations thereof.

In operation 1106 of method 1100, a first conductive material is deposited on a first level thereby forming a set of contacts. In some embodiments, the first level is the MD level.

In some embodiments, the set of contacts includes the set of contacts 806.

In operation 1108 of method 1100, a first set of vias is formed on the front-side of a wafer or substrate on a VD level (e.g., VD). In some embodiments, the first set of vias of method 1100 includes one or more portions of at least the set of vias 810.

In some embodiments, operation 1108 includes forming a first set of self-aligned contacts (SACs) in the insulating layer over the front-side of the wafer. In some embodiments, the first set of vias is electrically coupled to at least the set of contacts.

In operation 1110 of method 1100, a second set of vias is formed on the front-side of the wafer or substrate on a VG level (e.g., VG). In some embodiments, the second set of vias of method 1100 includes one or more portions of at least the set of vias 812.

In some embodiments, operation 1110 includes forming a second set of self-aligned contacts (SACs) in the insulating layer over the front-side of the wafer. In some embodiments, the second set of vias is electrically coupled to at least the set of gates.

In operation 1112 of method 1100, a second conductive material is deposited on a second level thereby forming a first set of conductors. In some embodiments, the second level is the M0 level.

In some embodiments, the first set of conductors includes the set of conductors 820.

In operation 1114 of method 1100, at least one of the set of gates or the set of contacts is electrically coupled to the first set of conductors. In some embodiments, operation 1114 is part of operation 1112.

In some embodiments, one or more of operations 1104, 1106, 1108, 1110 or 1112 of method 1100 includes using a combination of photolithography and material removal processes to form openings in an insulating layer (not shown) over the substrate. In some embodiments, the photolithography process includes patterning a photoresist, such as a positive photoresist or a negative photoresist. In some embodiments, the photolithography process includes forming a hard mask, an antireflective structure, or another suitable photolithography structure. In some embodiments, the material removal process includes a wet etching process, a dry etching process, an RIE process, laser drilling or another suitable etching process. The openings are then filled with conductive material, e.g., copper, aluminum, titanium, nickel, tungsten, or other suitable conductive material. In some embodiments, the openings are filled using CVD, PVD, sputtering, ALD or other suitable formation process.

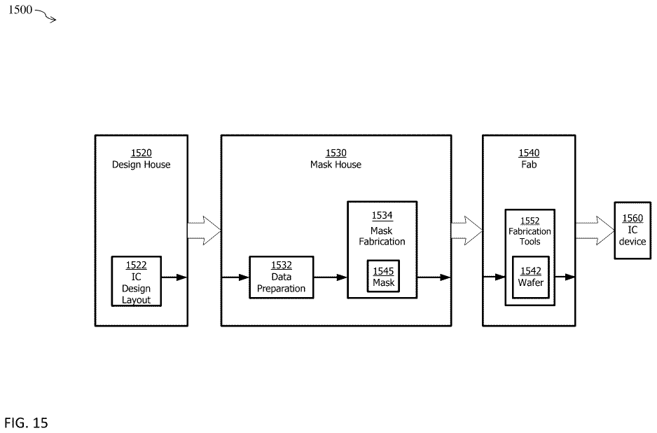

In some embodiments, at least one or more operations of method 1100 is performed by system 1500 of FIG. 15. In some embodiments, at least one method(s), such as method 1100 discussed above, is performed in whole or in part by at least one manufacturing system, including system 1500. One or more of the operations of method 1100 is performed by IC fab 1540 (FIG. 15) to fabricate IC device 1560. In some embodiments, one or more of the operations of method 1100 is performed by fabrication tools 1552 to fabricate wafer 1542.

In some embodiments, the conductive material includes copper, aluminum, titanium, nickel, tungsten, or other suitable conductive material. In some embodiments, the openings and trench are filled using CVD, PVD, sputtering, ALD or other suitable formation process. In some embodiments, after conductive material is deposited in one or more of operations 1104, 1106, 1108, 1110 or 1112, the conductive material is planarized to provide a level surface for subsequent steps.

In some embodiments, one or more of the operations of method 1100, 1200 or 1300 is not performed.

One or more of the operations of methods 1200-1300 is performed by a processing device configured to execute instructions for manufacturing an integrated circuit, such as at least integrated circuit 100A-100B, 200A-200B, 300A-300B, 400A-400B, 500A-500B, 600, 700A-700G, 800 or 900. In some embodiments, one or more operations of methods 1200-1300 is performed using a same processing device as that used in a different one or more operations of methods 1200-1300. In some embodiments, a different processing device is used to perform one or more operations of methods 1200-1300 from that used to perform a different one or more operations of methods 1200-1300. In some embodiments, other order of operations of method 1100, 1200 or 1300 is within the scope of the present disclosure. Method 1100, 1200 or 1300 includes exemplary operations, but the operations are not necessarily performed in the order shown. Operations in method 1100, 1200 or 1300 may be added, replaced, changed order, and/or eliminated as appropriate, in accordance with the spirit and scope of disclosed embodiments.

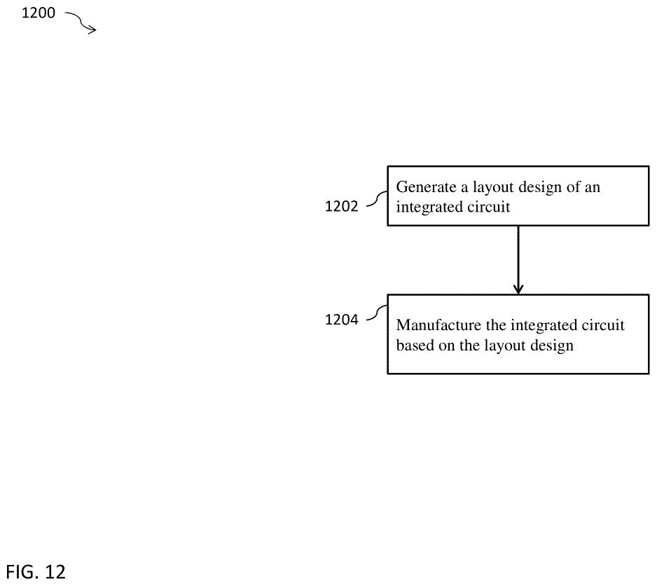

FIG. 12 is a flowchart of a method 1200 of forming or manufacturing an integrated circuit in accordance with some embodiments. It is understood that additional operations may be performed before, during, and/or after the method 1200 depicted in FIG. 12, and that some other operations may only be briefly described herein. In some embodiments, the method 1200 is usable to form integrated circuits, such as at least integrated circuit 100A-100B, 200A-200B, 300A-300B, 400A-400B, 500A-500B, 600, 700A-700G, 800 or 900.

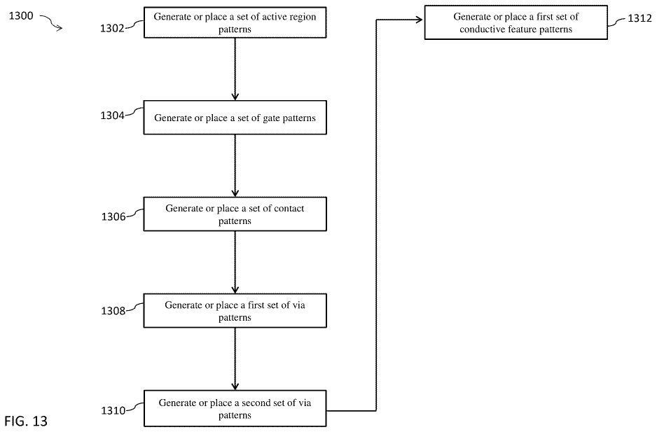

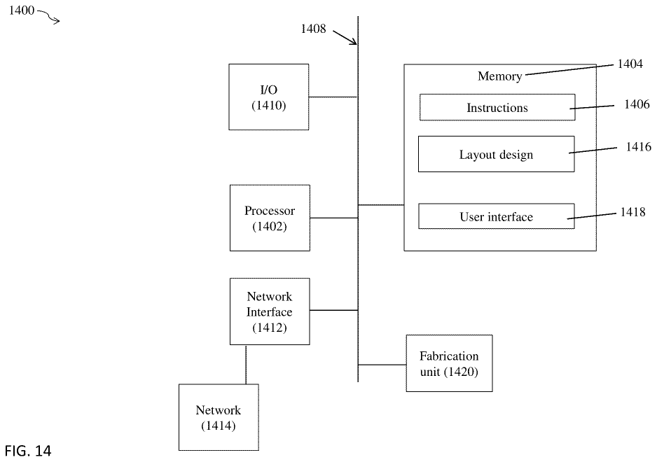

In operation 1202 of method 1200, a layout design of an integrated circuit is generated. Operation 1202 is performed by a processing device (e.g., processor 1402 (FIG. 14)) configured to execute instructions for generating a layout design. In some embodiments, the layout design of method 1200 includes one or more features similar to at least integrated circuit 100A-100B, 200A-200B, 300A-300B, 400A-400B, 500A-500B, 600, 700A-700G, 800 or 900. In some embodiments, the layout design of the present application is in a graphic database system (GDSII) file format. In some embodiments, operation 1202 corresponds to method 1300 of FIG. 13.

In operation 1204 of method 1200, the integrated circuit is manufactured based on the layout design. In some embodiments, operation 1204 of method 1200 comprises manufacturing at least one mask based on the layout design, and manufacturing the integrated circuit based on the at least one mask. In some embodiments, operation 1204 corresponds to method 1100 of FIG. 11.

FIG. 13 is a flowchart of a method 1300 of generating a layout design of an integrated circuit, in accordance with some embodiments. It is understood that additional operations may be performed before, during, and/or after the method 1300 depicted in FIG. 13, and that some other processes may only be briefly described herein. In some embodiments, method 1300 is an embodiment of operation 1202 of method 1200. In some embodiments, method 1300 is usable to generate one or more patterns or one or more features similar to at least integrated circuit 100A-100B, 200A-200B, 300A-300B, 400A-400B, 500A-500B, 600, 700A-700G, 800 or 900.

In some embodiments, method 1300 is usable to generate one or more layout patterns having structural relationships including alignment, lengths and widths, as well as configurations and layers of one or more features similar to at least integrated circuit 100A-100B, 200A-200B, 300A-300B, 400A-400B, 500A-500B, 600, 700A-700G, 800 or 900, and similar detailed description will not be described in FIG. 13, for brevity.

In operation 1302 of method 1300, a set of active region patterns is generated or placed on the layout design. In some embodiments, the set of active region patterns of method 1300 includes one or more regions similar to the set of active regions 802. In some embodiments, the set of active region patterns of method 1300 includes one or more patterns or similar patterns in the OD layer.

In operation 1304 of method 1300, a set of gate patterns is generated or placed on the layout design. In some embodiments, the set of gate patterns of method 1300 includes one or more patterns similar to the set of gates 804. In some embodiments, the set of gate patterns of method 1300 includes one or more patterns or similar patterns in the POLY layer.

In operation 1306 of method 1300, a set of contact patterns is generated or placed on the layout design. In some embodiments, the set of contact patterns of method 1300 includes one or more patterns similar to the set of contacts 806. In some embodiments, the set of contact patterns of method 1300 includes one or more patterns or similar patterns in the MD layer.

In operation 1308 of method 1300, a first set of via patterns is generated or placed on the layout design. In some embodiments, the first set of via patterns of method 1300 includes one or more via patterns similar to at least the set of vias 810. In some embodiments, the first set of via patterns of method 1300 includes one or more patterns or similar vias in the VD layer.

In operation 1310 of method 1300, a second set of via patterns is generated or placed on the layout design. In some embodiments, the second set of via patterns of method 1300 includes one or more via patterns similar to at least the set of vias 812. In some embodiments, the second set of via patterns of method 1300 includes one or more patterns or similar vias in the VG layer.

In operation 1312 of method 1300, a first set of conductive feature patterns is generated or placed on the layout design. In some embodiments, the first set of conductive feature patterns of method 1300 includes one or more patterns similar to the set of conductors 820. In some embodiments, the first set of conductive feature patterns of method 1300 includes one or more patterns or similar patterns in the M0 layer.

FIG. 14 is a schematic view of a system 1400 for designing an IC layout design and manufacturing an IC circuit, in accordance with some embodiments.

In some embodiments, system 1400 generates or places one or more IC layout designs described herein. System 1400 includes a hardware processor 1402 and a non-transitory, computer readable storage medium 1404 (e.g., memory 1404) encoded with, i.e., storing, the computer program code 1406, i.e., a set of executable instructions 1406. Computer readable storage medium 1404 is configured for interfacing with manufacturing machines for producing the integrated circuit. The processor 1402 is electrically coupled to the computer readable storage medium 1404 by a bus 1408. The processor 1402 is also electrically coupled to an I/O interface 1410 by bus 1408. A network interface 1412 is also electrically connected to the processor 1402 via bus 1408. Network interface 1412 is connected to a network 1414, so that processor 1402 and computer readable storage medium 1404 are capable of connecting to external elements by network 1414. The processor 1402 is configured to execute the computer program code 1406 (e.g., non-transitory instructions) encoded in the computer readable storage medium 1404 in order to cause system 1400 to be usable for performing a portion or all of the operations as described in method 1200-1300.

In some embodiments, the processor 1402 is a central processing unit (CPU), a multi-processor, a distributed processing system, an application specific integrated circuit (ASIC), and/or a suitable processing unit.

In some embodiments, the computer readable storage medium 1404 is an electronic, magnetic, optical, electromagnetic, infrared, and/or a semiconductor system (or apparatus or device). For example, the computer readable storage medium 1404 includes a semiconductor or solid-state memory, a magnetic tape, a removable computer diskette, a random access memory (RAM), a read-only memory (ROM), a rigid magnetic disk, and/or an optical disk. In some embodiments using optical disks, the computer readable storage medium 1404 includes a compact disk-read only memory (CD-ROM), a compact disk-read/write (CD-R/W), and/or a digital video disc (DVD). In some embodiments, the computer readable storage medium 1404 is a non-transitory computer readable storage medium.

In some embodiments, the storage medium 1404 stores the computer program code 1406 configured to cause system 1400 to perform method 1200-1300. In some embodiments, the storage medium 1404 also stores information needed for performing method 1200-1300 as well as information generated during performing method 1200-1300, such as layout design 1416, user interface 1418 and fabrication unit 1420, and/or a set of executable instructions to perform the operation of method 1200-1300. In some embodiments, layout design 1416 comprises one or more patterns or features similar to at least integrated circuit 800.

In some embodiments, the storage medium 1404 stores instructions (e.g., computer program code 1406) for interfacing with manufacturing machines. The instructions (e.g., computer program code 1406) enable processor 1402 to generate manufacturing instructions readable by the manufacturing machines to effectively implement method 1200-1300 during a manufacturing process.

System 1400 includes I/O interface 1410. I/O interface 1410 is coupled to external circuitry. In some embodiments, I/O interface 1410 includes a keyboard, keypad, mouse, trackball, trackpad, and/or cursor direction keys for communicating information and commands to processor 1402.

System 1400 also includes network interface 1412 coupled to the processor 1402. Network interface 1412 allows system 1400 to communicate with network 1414, to which one or more other computer systems are connected. Network interface 1412 includes wireless network interfaces such as BLUETOOTH, WIFI, WIMAX, GPRS, or WCDMA; or wired network interface such as ETHERNET, USB, or IEEE-2094. In some embodiments, method 1200-1300 is implemented in two or more systems 1400, and information such as layout design, and user interface are exchanged between different systems 1400 by network 1414.

System 1400 is configured to receive information related to a layout design through I/O interface 1410 or network interface 1412. The information is transferred to processor 1402 by bus 1408 to determine a layout design for producing at least integrated circuit 100A-100B, 200A-200B, 300A-300B, 400A-400B, 500A-500B, 600, 700A-700G, 800 or 900. The layout design is then stored in computer readable medium 1404 as layout design 1416. System 1400 is configured to receive information related to a user interface through I/O interface 1410 or network interface 1412. The information is stored in computer readable medium 1404 as user interface 1418. System 1400 is configured to receive information related to a fabrication unit 1420 through I/O interface 1410 or network interface 1412. The information is stored in computer readable medium 1404 as fabrication unit 1420. In some embodiments, the fabrication unit 1420 includes fabrication information utilized by system 1400. In some embodiments, the fabrication unit 1420 corresponds to mask fabrication 1534 of FIG. 15.

In some embodiments, method 1200-1300 is implemented as a standalone software application for execution by a processor. In some embodiments, method 1200-1300 is implemented as a software application that is a part of an additional software application. In some embodiments, method 1200-1300 is implemented as a plug-in to a software application. In some embodiments, method 1200-1300 is implemented as a software application that is a portion of an EDA tool. In some embodiments, method 1200-1300 is implemented as a software application that is used by an EDA tool. In some embodiments, the EDA tool is used to generate a layout of the integrated circuit device. In some embodiments, the layout is stored on a non-transitory computer readable medium. In some embodiments, the layout is generated using a tool such as VIRTUOSO® available from CADENCE DESIGN SYSTEMS, Inc., or another suitable layout generating tool. In some embodiments, the layout is generated based on a netlist which is created based on the schematic design. In some embodiments, method 1200-1300 is implemented by a manufacturing device to manufacture an integrated circuit using a set of masks manufactured based on one or more layout designs generated by system 1400. In some embodiments, system 1400 is a manufacturing device configured to manufacture an integrated circuit using a set of masks manufactured based on one or more layout designs of the present disclosure. In some embodiments, system 1400 of FIG. 14 generates layout designs of an integrated circuit that are smaller than other approaches. In some embodiments, system 1400 of FIG. 14 generates layout designs of integrated circuit structure that occupy less area and provide better routing resources than other approaches.

FIG. 15 is a block diagram of an integrated circuit (IC) manufacturing system 1500, and an IC manufacturing flow associated therewith, in accordance with at least one embodiment of the present disclosure. In some embodiments, based on a layout diagram, at least one of (A) one or more semiconductor masks or (B) at least one component in a layer of a semiconductor integrated circuit is fabricated using manufacturing system 1500.

In FIG. 15, IC manufacturing system 1500 (hereinafter “system 1500”) includes entities, such as a design house 1520, a mask house 1530, and an IC manufacturer/fabricator (“fab”) 1540, that interact with one another in the design, development, and manufacturing cycles and/or services related to manufacturing an IC device 1560. The entities in system 1500 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, one or more of design house 1520, mask house 1530, and IC fab 1540 is owned by a single larger company. In some embodiments, one or more of design house 1520, mask house 1530, and IC fab 1540 coexist in a common facility and use common resources.

Design house (or design team) 1520 generates an IC design layout 1522. IC design layout 1522 includes various geometrical patterns designed for an IC device 1560. The geometrical patterns correspond to patterns of metal, oxide, or semiconductor layers that make up the various components of IC device 1560 to be fabricated. The various layers combine to form various IC features. For example, a portion of IC design layout 1522 includes various IC features, such as an active region, gate electrode, source electrode and drain electrode, metal lines or vias of an interlayer interconnection, and openings for bonding pads, to be formed in a semiconductor substrate (such as a silicon wafer) and various material layers disposed on the semiconductor substrate. Design house 1520 implements a proper design procedure to form IC design layout 1522. The design procedure includes one or more of logic design, physical design or place and route. IC design layout 1522 is presented in one or more data files having information of the geometrical patterns. For example, IC design layout 1522 can be expressed in a GDSII file format or DFII file format.

Mask house 1530 includes data preparation 1532 and mask fabrication 1534. Mask house 1530 uses IC design layout 1522 to manufacture one or more masks 1545 to be used for fabricating the various layers of IC device 1560 according to IC design layout 1522. Mask house 1530 performs mask data preparation 1532, where IC design layout 1522 is translated into a representative data file (RDF). Mask data preparation 1532 provides the RDF to mask fabrication 1534. Mask fabrication 1534 includes a mask writer. A mask writer converts the RDF to an image on a substrate, such as a mask (reticle) 1545 or a semiconductor wafer 1542. The IC design layout 1522 is manipulated by mask data preparation 1532 to comply with particular characteristics of the mask writer and/or requirements of IC fab 1540. In FIG. 15, mask data preparation 1532 and mask fabrication 1534 are illustrated as separate elements. In some embodiments, mask data preparation 1532 and mask fabrication 1534 can be collectively referred to as mask data preparation.

In some embodiments, mask data preparation 1532 includes optical proximity correction (OPC) which uses lithography enhancement techniques to compensate for image errors, such as those that can arise from diffraction, interference, other process effects and the like. OPC adjusts IC design layout 1522. In some embodiments, mask data preparation 1532 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, mask data preparation 1532 includes a mask rule checker (MRC) that checks the IC design layout that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout to compensate for limitations during mask fabrication 1534, which may undo part of the modifications performed by OPC in order to meet mask creation rules.

In some embodiments, mask data preparation 1532 includes lithography process checking (LPC) that simulates processing that will be implemented by IC fab 1540 to fabricate IC device 1560. LPC simulates this processing based on IC design layout 1522 to create a simulated manufactured device, such as IC device 1560. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (DOF), mask error enhancement factor (MEEF), other suitable factors, and the like or combinations thereof. In some embodiments, after a simulated manufactured device has been created by LPC, if the simulated device is not close enough in shape to satisfy design rules, OPC and/or MRC are be repeated to further refine IC design layout 1522.

It should be understood that the above description of mask data preparation 1532 has been simplified for the purposes of clarity. In some embodiments, data preparation 1532 includes additional features such as a logic operation (LOP) to modify the IC design layout according to manufacturing rules. Additionally, the processes applied to IC design layout 1522 during data preparation 1532 may be executed in a variety of different orders.

After mask data preparation 1532 and during mask fabrication 1534, a mask 1545 or a group of masks 1545 are fabricated based on the modified IC design layout 1522. In some embodiments, mask fabrication 1534 includes performing one or more lithographic exposures based on IC design layout 1522. In some embodiments, an electron-beam (e-beam) or a mechanism of multiple e-beams is used to form a pattern on a mask (photomask or reticle) 1545 based on the modified IC design layout 1522. The mask 1545 can be formed in various technologies. In some embodiments, the mask 1545 is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region and transmits through the transparent regions. In one example, a binary version of mask 1545 includes a transparent substrate (e.g., fused quartz) and an opaque material (e.g., chromium) coated in the opaque regions of the binary mask. In another example, the mask 1545 is formed using a phase shift technology. In the phase shift mask (PSM) version of mask 1545, various features in the pattern formed on the mask are configured to have proper phase difference to enhance the resolution and imaging quality. In various examples, the phase shift mask can be attenuated PSM or alternating PSM. The mask(s) generated by mask fabrication 1534 is used in a variety of processes. For example, such a mask(s) is used in an ion implantation process to form various doped regions in the semiconductor wafer, in an etching process to form various etching regions in the semiconductor wafer, and/or in other suitable processes.

IC fab 1540 is an IC fabrication entity that includes one or more manufacturing facilities for the fabrication of a variety of different IC products. In some embodiments, IC Fab 1540 is a semiconductor foundry. For example, there may be a manufacturing facility for the front end fabrication of a plurality of IC products (front-end-of-line (FEOL) fabrication), while a second manufacturing facility may provide the back end fabrication for the interconnection and packaging of the IC products (back-end-of-line (BEOL) fabrication), and a third manufacturing facility may provide other services for the foundry entity.

IC fab 1540 includes wafer fabrication tools 1552 (hereinafter “fabrication tools 1552”) configured to execute various manufacturing operations on semiconductor wafer 1542 such that IC device 1560 is fabricated in accordance with the mask(s), e.g., mask 1545. In various embodiments, fabrication tools 1552 include one or more of a wafer stepper, an ion implanter, a photoresist coater, a process chamber, e.g., a CVD chamber or LPCVD furnace, a CMP system, a plasma etch system, a wafer cleaning system, or other manufacturing equipment capable of performing one or more suitable manufacturing processes as discussed herein.

IC fab 1540 uses mask(s) 1545 fabricated by mask house 1530 to fabricate IC device 1560. Thus, IC fab 1540 at least indirectly uses IC design layout 1522 to fabricate IC device 1560. In some embodiments, a semiconductor wafer 1542 is fabricated by IC fab 1540 using mask(s) 1545 to form IC device 1560. In some embodiments, the IC fabrication includes performing one or more lithographic exposures based at least indirectly on IC design layout 1522. Semiconductor wafer 1542 includes a silicon substrate or other proper substrate having material layers formed thereon. Semiconductor wafer 1542 further includes one or more of various doped regions, dielectric features, multilevel interconnects, and the like (formed at subsequent manufacturing steps).

System 1500 is shown as having design house 1520, mask house 1530 or IC fab 1540 as separate components or entities. However, it is understood that one or more of design house 1520, mask house 1530 or IC fab 1540 are part of the same component or entity.

Other diode types or numbers of diodes, or transistor types or other numbers of transistors in at least integrated circuit 100A-100B, 200A-200B, 300A-300B, 400A-400B, 500A-500B, 600, 700A-700G, 800 or 900 are within the scope of the present disclosure.

Furthermore, various NMOS or PMOS transistors shown in FIGS. 2A-6 and 9 are of a particular dopant type (e.g., N-type or P-type) and are for illustration purposes. Embodiments of the disclosure are not limited to a particular transistor type, and one or more of the PMOS or NMOS transistors shown in FIGS. 2A-6 and 9 can be substituted with a corresponding transistor of a different transistor/dopant type. Similarly, the low or high logical value of various signals used in the above description is also used for illustration. Embodiments of the disclosure are not limited to a particular logical value when a signal is activated and/or deactivated. Selecting different logical values is within the scope of various embodiments. Selecting different numbers of PMOS transistors in FIGS. 2A-6 and 9 is within the scope of various embodiments.

One aspect of this description relates to integrated circuit. In some embodiments, the integrated circuit includes a buffer circuit coupled between a first node and a second node. In some embodiments, the integrated circuit further includes an input/output (IO) pad coupled to the buffer circuit, the buffer circuit being configured to output a first signal to the IO pad. In some embodiments, the integrated circuit further includes a first clamp circuit coupled between the IO pad and the second node, and being configured to clamp a first electrostatic discharge (ESD) event at the IO pad or the second node. In some embodiments, the integrated circuit further includes a second clamp circuit coupled between the IO pad and the first node, and being configured to clamp a second ESD event at the IO pad or the first node.

Another aspect of this description relates to an integrated circuit. In some embodiments, the integrated circuit includes a buffer circuit including an input and an output, and being coupled between a first node and a second node. In some embodiments, the integrated circuit further includes an input/output (IO) pad coupled to the output of the buffer circuit, the IO pad being configured to receive a first signal from the buffer circuit. In some embodiments, the integrated circuit further includes a first clamp circuit coupled between the IO pad and the second node, and being configured to clamp a first electrostatic discharge (ESD) event at the IO pad or the second node. In some embodiments, the integrated circuit further includes a second clamp circuit coupled between the IO pad and the first node, and being configured to clamp a second ESD event at the IO pad or the first node. In some embodiments, the integrated circuit further includes a header circuit coupled between the first node and a third node, the header circuit coupled to a first voltage supply having a first supply voltage, and being configured to provide the first supply voltage to the first node in response to a control signal.

Yet another aspect of this description relates to a method of operating an ESD circuit. In some embodiments, the method includes receiving a first ESD voltage on a first node, the first ESD voltage being greater than a reference supply voltage of a reference voltage supply, the first ESD voltage corresponding to a first ESD event. In some embodiments, the method further includes detecting, by a first ESD detection circuit, the first ESD event at the first node thereby causing the first ESD detection circuit to turn on and charge a first gate of a first transistor of a first discharging circuit, the first transistor being coupled between the first node and a second node, and the first ESD detection circuit being coupled between at least the first node and the second node. In some embodiments, the method further includes discharging a first ESD current of the first ESD event in a first ESD direction from the first node to the second node by the first transistor.

A number of embodiments have been described. It will nevertheless be understood that various modifications may be made without departing from the spirit and scope of the disclosure. For example, various transistors being shown as a particular dopant type (e.g., N-type or P-type Metal Oxide Semiconductor (NMOS or PMOS)) are for illustration purposes. Embodiments of the disclosure are not limited to a particular type. Selecting different dopant types for a particular transistor is within the scope of various embodiments. The low or high logical value of various signals used in the above description is also for illustration. Various embodiments are not limited to a particular logical value when a signal is activated and/or deactivated. Selecting different logical values is within the scope of various embodiments. In various embodiments, a transistor functions as a switch. A switching circuit used in place of a transistor is within the scope of various embodiments. In various embodiments, a source of a transistor can be configured as a drain, and a drain can be configured as a source. As such, the term source and drain are used interchangeably. Various signals are generated by corresponding circuits, but, for simplicity, the circuits are not shown.

Various figures show capacitive circuits using discrete capacitors for illustration. Equivalent circuitry may be used. For example, a capacitive device, circuitry or network (e.g., a combination of capacitors, capacitive elements, devices, circuitry, or the like) can be used in place of the discrete capacitor. The above illustrations include exemplary steps, but the steps are not necessarily performed in the order shown. Steps may be added, replaced, changed order, and/or eliminated as appropriate, in accordance with the spirit and scope of disclosed embodiments.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit comprising:
a buffer circuit coupled between a first node and a second node;
an input/output (IO) pad coupled to the buffer circuit, the buffer circuit being configured to output a first signal to the IO pad;
a first clamp circuit coupled between the IO pad and the second node, and being configured to clamp a first electrostatic discharge (ESD) event at the IO pad or the second node; and
a second clamp circuit coupled between the IO pad and the first node, and being configured to clamp a second ESD event at the IO pad or the first node.

2. The integrated circuit of claim 1, wherein the first clamp circuit comprises:
a first ESD detection circuit coupled between the IO pad and the second node; and
a first transistor of a first type, the first transistor including a first gate coupled to at least the first ESD detection circuit by a third node, a first drain coupled to the IO pad and a first source coupled to the second node.

3. The integrated circuit of claim 2, wherein the first ESD detection circuit comprises:
a first set of diodes serially coupled to each other, and coupled between the IO pad and the third node; and
a first resistor coupled between the third node and the second node.

4. The integrated circuit of claim 3, wherein the first set of diodes comprises:
a first diode including a first anode and a first cathode, the first anode being coupled to the IO pad;
a second diode including a second anode and a second cathode, the second anode being coupled to the first cathode; and
a third diode including a third anode and a third cathode, the third anode being coupled to the second cathode.

5. The integrated circuit of claim 4, wherein the third cathode is coupled to the third node, the first gate and a first end of the first resistor.

6. The integrated circuit of claim 4, wherein the first clamp circuit further comprises:
a fourth diode including a fourth anode and a fourth cathode, the fourth anode being coupled to the IO pad, and the fourth cathode being coupled to the first drain.

7. The integrated circuit of claim 6, wherein the first set of diodes further comprises:
a fifth diode including a fifth anode and a fifth cathode, the fifth anode being coupled to the third cathode, and the fifth cathode being coupled to the third node, the first gate and a first end of the first resistor.

8. The integrated circuit of claim 7, wherein the second clamp circuit comprises:
a second ESD detection circuit coupled between the IO pad and the first node; and
a second transistor of a second type different from the first type, the second transistor including a second gate coupled to at least the second ESD detection circuit by a fourth node, a second drain coupled to the IO pad and a second source coupled to the second node.

9. The integrated circuit of claim 8, wherein the second ESD detection circuit comprises:
a second set of diodes serially coupled to each other and coupled between the IO pad and the fourth node; and
a second resistor coupled between the fourth node and the first node.

10. The integrated circuit of claim 9, wherein the second set of diodes comprises:
a sixth diode including a sixth anode and a sixth cathode, the sixth anode being coupled to the fourth node, the second gate and a first end of the second resistor;
a seventh diode including a seventh anode and a seventh cathode, the seventh anode being coupled to the sixth cathode; and
an eighth diode including an eighth anode and an eighth cathode, the eighth anode being coupled to the seventh cathode.

11. The integrated circuit of claim 10, wherein the second clamp circuit further comprises:
a ninth diode including a ninth anode and a ninth cathode, the ninth anode being coupled to the second drain, and the ninth cathode being coupled to the IO pad.

12. The integrated circuit of claim 11, wherein the second set of diodes further comprises:
a tenth diode including a tenth anode and a tenth cathode, the tenth anode being coupled to the eighth cathode, and the tenth cathode being coupled to the IO pad and the ninth cathode.

13. An integrated circuit comprising:
a buffer circuit including an input and an output, and being coupled between a first node and a second node;
an input/output (IO) pad coupled to the output of the buffer circuit, the IO pad being configured to receive a first signal from the buffer circuit;
a first clamp circuit coupled between the IO pad and the second node, and being configured to clamp a first electrostatic discharge (ESD) event at the IO pad or the second node;
a second clamp circuit coupled between the IO pad and the first node, and being configured to clamp a second ESD event at the IO pad or the first node; and
a header circuit coupled between the first node and a third node, the header circuit coupled to a first voltage supply having a first supply voltage, and being configured to provide the first supply voltage to the first node in response to a control signal.

14. The integrated circuit of claim 13, further comprising:
a third clamp circuit coupled between the third node and the second node.

15. The integrated circuit of claim 14, further comprising:
a capacitor coupled between the first node and the second node; and
an internal circuit coupled to the input of the buffer circuit.

16. The integrated circuit of claim 15, further comprising:
a fourth clamp circuit coupled between the first node and the second node.

17. The integrated circuit of claim 13, wherein the first clamp circuit comprises:
a first current mirror coupled to at least the IO pad, a first path and a second path;
a first set of diodes serially coupled to each other, and being coupled to the first current mirror by the second path;
a first resistor coupled to the second path, the first set of diodes, a fourth node and the second node;
a first transistor of a first type, the first transistor including a first gate coupled to at least the fourth node and the first resistor, a first drain coupled to the IO pad, and a first source coupled to the second node; and
a first diode including a first anode and a first cathode, the first anode being coupled to the IO pad, and the first cathode being coupled to the second node and the first resistor.

18. The integrated circuit of claim 17, wherein the first clamp circuit further comprises:
a second transistor of the first type, the second transistor including a second gate coupled to the first gate, the first set of diodes, the fourth node and the first resistor, a second drain coupled to the first current mirror by the first path and a second source coupled to the second node and the first source.

19. The integrated circuit of claim 18, wherein the first current mirror comprises:
a third transistor of a second type different from the first type, the third transistor including a third gate, a third drain, and a third source; and
a fourth transistor of the second type, the fourth transistor including a fourth gate, a fourth drain, and a fourth source;
wherein each of the third source, the fourth source, the IO pad and the first anode are coupled to each other;
each of the third gate, the third drain, the fourth gate and the first set of diodes are coupled to each other; and
the fourth drain is coupled to the second drain by the first path.

20. A method of operating an electrostatic discharge (ESD) circuit, the method comprising:
receiving a first ESD voltage on a first node, the first ESD voltage being greater than a reference supply voltage of a reference voltage supply, the first ESD voltage corresponding to a first ESD event;
detecting, by a first ESD detection circuit, the first ESD event at the first node thereby causing the first ESD detection circuit to turn on and charge a first gate of a first transistor of a first discharging circuit, the first transistor being coupled between the first node and a second node, and the first ESD detection circuit being coupled between at least the first node and the second node; and
discharging a first ESD current of the first ESD event in a first ESD direction from the first node to the second node by the first transistor.
